(19) United States
(12) Patent Application Publication
(10) Pub. No.: US 2024/0079522 A1
(43) Pub. Date: Mar. 7, 2024

(54) LIGHT-EMITTING DEVICE AND METHOD FOR MANUFACTURING THE SAME

(71) Applicant: LG Display Co., Ltd., Seoul (KR)

(72) Inventors: Dongwon YANG, Seoul (KR); Jung-Hun CHOI, Paju-si (KR)

(73) Assignee: LG Display Co., Ltd., Seoul (KR)

(21) Appl. No.: 18/234,734

(22) Filed: Aug. 16, 2023

(30) Foreign Application Priority Data
Sep. 6, 2022 (KR) 10-2022-0112694

(51) Int. Cl. H01L 33/20; H01L 33/00; H01L 33/44

(52) U.S. Cl. CPC H01L 33/20; H01L 33/0075; H01L 33/44; H01L 33/32; H01L 2933/0025

(57) ABSTRACT

A light-emitting device and a method for manufacturing the light-emitting device are discussed. The light-emitting device can include a nitride semiconductor structure including a first semiconductor layer, an active layer and a second semiconductor layer; a passivation pattern disposed on opposing side surfaces of the nitride semiconductor structure; a first electrode electrically connected to the first semiconductor layer; and a second electrode electrically connected to the second semiconductor layer. An upper surface of the passivation pattern can be disposed to be substantially coplanar with an upper surface of the second semiconductor layer.

### CROSS-REFERENCE TO RELATED APPLICATION

This application claims priority to Korean Patent Application No. 10-2022-0112694 filed on Sep. 6, 2022 in the Republic of Korea, and all the benefits accruing therefrom under 35 U.S.C. § 119, the entire contents of the Korean Application being expressly incorporated by reference into the present application.

### BACKGROUND

### Field

The present disclosure relates to a light-emitting device, and a method for manufacturing the light-emitting device. More specifically, the present disclosure relates to a light-emitting device capable of preventing damage to the light-emitting device, and a method for manufacturing the light-emitting device.

### Discussion of the Related Art

A display device is applied to various electronic devices such as TVs, mobile phones, laptops, and tablets.

Among the display devices, a light-emitting display device has a light-emitting element or a light source built therein and displays information using light generated from the built-in light-emitting element or light source.

A display device including a self-light-emitting element can be implemented to be thinner than a display device with the built-in light source, and can be implemented as a flexible display device that can be folded, bent, or rolled.

The display device having the self-light-emitting element can include, for example, an organic light-emitting display device (OLED) including a light-emitting layer made of an organic material, or a micro-LED (micro-light emitting diode) display device including a light-emitting layer made of an inorganic material.

In this regard, the organic light-emitting display device does not require a separate light source. However, due to material characteristics of the organic material that is vulnerable to moisture and oxygen, a defective pixel may occur in the organic light-emitting display device due to an external environment. On the contrary, the micro-LED display device includes a light-emitting layer made of an inorganic material that is resistant to moisture and oxygen and thus may not be affected by the external environment. As such, the microOLED display device can have high reliability and high image quality compared to the organic light-emitting display device.

Further, the micro-LED display device is resistant to the external environment, and does not require a protective structure such as a sealing material. As such, various types of materials can be used as a material of a substrate of the micro-LED display device, thereby implementing a flexible display device with a thinner structure than that of the organic light-emitting display device. Due to such advantageous features, the micro-LED display device is in the limelight as a next-generation display device.

### SUMMARY OF THE DISCLOSURE

A technical purpose according to an embodiment of the present disclosure is to provide a light-emitting device which prevents a side surface of a nitride semiconductor structure of the light-emitting device from being damaged, thereby securing an area where combinations of electrons and holes that participate in light emission occurs.

Further, a technical purpose according to an embodiment of the present disclosure is to vary a shape of the nitride semiconductor structure to improve light-emitting efficiency thereof.

Further, a technical purpose according to an embodiment of the present disclosure is to change a position of a pad electrode of the light-emitting device to improve a size of a light-emitting area of the light-emitting device.

Further, a technical purpose according to an embodiment of the present disclosure is to provide a method for manufacturing a light-emitting element in which during a patterning process for forming the nitride semiconductor structure of the light-emitting element, the nitride semiconductor structure can be prevented from being damaged by plasma, so as to suppress or minimize abnormal combinations of electrons-holes that do not participate in light emission.

Further, a technical purpose according to an embodiment of the present disclosure is to provide a method for manufacturing a light-emitting element in which a passivation pattern is pre-formed to pre-specify a position where the nitride semiconductor structure is to be formed, such that the nitride semiconductor structure can be easily formed.

Further, a technical purpose according to an embodiment of the present disclosure is to provide a method for manufacturing a light-emitting element in which the nitride semiconductor layer is grown while a contact area between the growth substrate and the nitride semiconductor layer is reduced in an epitaxy process for forming the nitride semiconductor structure, thereby improving quality of the nitride semiconductor layer.

Further, a technical purpose according to one embodiment of the present disclosure is to improve current injection efficiency of a light-emitting element by using a current confinement phenomenon, which is achieved based on a shape of the nitride semiconductor structure.

Purposes according to the present disclosure are not limited to the above-mentioned purpose. Other purposes and advantages according to the present disclosure that are not mentioned can be understood based on following descriptions, and can be more clearly understood based on embodiments according to the present disclosure. Further, it will be easily understood that the purposes and advantages according to the present disclosure can be realized using means shown in the claims or combinations thereof.

A first aspect of the present disclosure provides a light-emitting device comprising: a nitride semiconductor structure including a first semiconductor layer, an active layer and a second semiconductor layer; a passivation pattern disposed on both opposing side surfaces of the nitride semiconductor structure; a first electrode electrically connected to the first semiconductor layer; and a second electrode electrically connected to the second semiconductor layer, wherein an upper surface of the passivation pattern is coplanar or substantially coplanar with an upper surface of the second semiconductor layer.

In one implementation of the light-emitting device, the nitride semiconductor structure further includes an undoped semiconductor layer disposed under the first semiconductor layer.

In one implementation of the light-emitting device, one side surface of the nitride semiconductor structure is aligned in a line, wherein the other side surface opposite to the one side surface of the nitride semiconductor structure has a step such that a portion of an upper surface of the first semiconductor layer is exposed.

In one implementation of the light-emitting device, the passivation pattern has a contact hole exposing a portion of the exposed portion of the upper surface of the first semiconductor layer, wherein the first electrode includes: a column portion filling the contact hole to be connected to the first semiconductor layer; and a head portion extending from the column portion and disposed on an upper surface of the passivation pattern, wherein at least a partial area of the second electrode overlaps the upper surface of the passivation pattern.

In one implementation of the light-emitting device, each of the second semiconductor layer and the active layer has a first width, wherein the first semiconductor layer includes an upper portion having a width equal to the first width, and a lower portion having a second width larger than the first width, wherein the lower portion of the first semiconductor layer has a protruding portion extending outwardly beyond each of both opposing sidewalls of the upper portion of the first semiconductor layer, wherein the protruding portion has an exposed upper surface.

In one implementation of the light-emitting device, wherein the passivation pattern has a contact hole defined therein exposing a portion of the exposed upper surface of the protruding portion of the lower portion of the first semiconductor layer at one side of the lower portion, wherein the first electrode includes: a column portion filling the contact hole to be connected to the first semiconductor layer; and a head portion extending from the column portion and disposed on the upper surface of the passivation pattern, wherein at least a partial area of the second electrode overlaps the upper surface of the passivation pattern.

In one implementation of the light-emitting device, each of both opposing side surfaces of the first semiconductor layer, each of both opposing side surfaces of the active layer, and each of both opposing side surfaces of the second semiconductor layer in the nitride semiconductor structure are aligned with each other in a line.

In one implementation of the light-emitting device, the nitride semiconductor structure further includes an undoped semiconductor layer disposed under the first semiconductor layer, wherein the undoped semiconductor layer has a protruding portion extending outwardly beyond an outer side surface of each of the first semiconductor layer, the active layer, and the second semiconductor layer, wherein the protruding portion has an exposed upper surface, wherein the passivation pattern is disposed on the exposed upper surface of the protruding portion of the undoped semiconductor layer.

In one implementation of the light-emitting device, each of the second semiconductor layer and the active layer has a first width, wherein the first semiconductor layer includes an upper portion having a width equal to the first width, and a lower portion having a second width smaller than the first width such that the first semiconductor layer has a step at each of both opposing side surfaces thereof, wherein the nitride semiconductor structure further includes an undoped semiconductor layer having a width equal to the second width.

In one implementation of the light-emitting device, the passivation pattern covers both opposing sidewalls of each of the second semiconductor layer and the active layer, and covers both opposing sidewalls and a bottom surface of the upper portion of the first semiconductor layer, and covers both opposing sidewalls of each of the lower portion of the first semiconductor layer and the undoped semiconductor layer.

In one implementation of the light-emitting device, the nitride semiconductor structure has a T-shape in a cross-sectional view of the device.

In one implementation of the light-emitting device, the nitride semiconductor structure further includes an undoped semiconductor layer disposed under the first semiconductor layer, wherein the passivation pattern includes: a first pattern portion surrounding an outer side surface of the nitride semiconductor structure; and a second pattern portion including a plurality of column portions spaced apart from each other, wherein each of the plurality of column portions extends through the undoped semiconductor layer to be disposed in the first semiconductor layer.

In one implementation of the light-emitting device, a spacing between adjacent ones of the plurality of column portions of the second pattern portion is smaller than a width of the active layer.

In one implementation of the light-emitting device, the nitride semiconductor structure further includes an undoped semiconductor layer disposed under the first semiconductor layer, wherein the nitride semiconductor structure has: a first side wall surface having a first slope in a first direction such that the width decreases toward the first semiconductor layer from the second semiconductor layer; and, a second side wall surface extending from the one side wall surface and having a second slope in a second direction such that the width increases in a direction from the first semiconductor layer toward the undoped semiconductor layer and the second direction is opposite to the first direction of the first slope.

In one implementation of the light-emitting device, in a cross-sectional view of the device, the nitride semiconductor structure has an hourglass shape having a smallest width at a median vertical level of nitride semiconductor structure.

In one implementation of the light-emitting device, the passivation pattern includes: a head portion having a taper shape; and a column portion extending from the head portion and having a reverse taper shape.

In one implementation of the light-emitting device, the passivation pattern includes a non-conductive material.

In one implementation of the light-emitting device, the first electrode or the second electrode has an exposed upper surface and an exposed side surface.

A second aspect of the present disclosure provides a method for manufacturing a light-emitting device, the method comprising: forming a plurality of body portions of a passivation pattern on the growth substrate so as to be spaced apart from each other via a first space; sequentially forming an undoped semiconductor layer and a lower portion of a first semiconductor layer in the first space; forming an extension of the passivation pattern on each of the body portions of the passivation pattern so as to overlap a portion of the lower portion of the first semiconductor layer; sequentially forming an upper portion of the first semiconductor layer, an active layer, and a second semiconductor layer in a second space defined between adjacent extensions of the passivation pattern, thereby forming a nitride semiconductor structure; etching the passivation pattern to space adjacent nitride semiconductor structures from each other; and removing the growth substrate from the nitride semiconductor structures.

In one implementation the method further comprises: after spacing the adjacent nitride semiconductor structures from each other, forming a contact hole extending through the passivation pattern so as to expose a portion of a surface of the lower portion of the first semiconductor layer; forming a first electrode such that the first electrode includes a column portion filling the contact hole so as to be connected to the exposed portion of the surface of the lower portion of the first semiconductor layer, and a head portion extending from the column portion so as to be disposed on an upper surface of the passivation pattern; and forming a second electrode on a surface of the second semiconductor layer such that a portion of a lower surface of the second electrode overlaps the upper surface of the passivation pattern.

In one implementation of the method, etching the passivation pattern includes etching the passivation pattern in a dry etching scheme using plasma.

In one implementation of the method, spacing adjacent nitride semiconductor structures from each other is performed such that a remaining portion of the passivation pattern after the etching thereof surrounds an outer side surface of the nitride semiconductor structure.

In one implementation of the method, the passivation pattern includes an insulating material on which nitride semiconductor does not grow.

A third aspect of the present disclosure provides a method for manufacturing a light-emitting device, the method comprising: forming a plurality of passivation patterns on a growth substrate so as to be spaced apart from each other via a space of a shape corresponding to a shape of a nitride semiconductor structure; forming a nitride semiconductor structure in the space defined between adjacent passivation patterns, wherein the nitride semiconductor structure includes a first semiconductor layer, an active layer, and a second semiconductor layer; exposing a portion of an upper surface of each of the passivation patterns; etching the exposed portion of the upper surface of the passivation pattern until a surface of the growth substrate is exposed, thereby spacing adjacent nitride semiconductor structures from each other; and removing the growth substrate from the nitride semiconductor structures.

In one implementation of the method, forming the nitride semiconductor structure further includes forming an undoped semiconductor layer under the first semiconductor layer.

In one implementation of the method, the undoped semiconductor layer has a width equal to a width of each of the first semiconductor layer, the active layer, and the second semiconductor layer.

In one implementation of the method, the undoped semiconductor layer has a portion protruding outwardly beyond an outer sidewall of each of the first semiconductor layer, the active layer, and the second semiconductor layer such that the undoped semiconductor layer has a width larger than a width of each of the first semiconductor layer, the active layer, and the second semiconductor layer, wherein the passivation pattern is disposed on an upper surface of the protruding portion of the undoped semiconductor layer.

In one implementation of the method, the passivation pattern has: a column portion having a reverse taper shape in which a width thereof gradually decrease as the column portion extends toward the growth substrate; and a head portion extending from the column portion and having a taper shape in which a width thereof gradually decrease as the head portion extends toward the second semiconductor layer.

In one implementation of the method, the nitride semiconductor structure has an hourglass shape in which a width thereof is the smallest at a median vertical level thereof, and is the largest at each of bottom and top levels thereof.

In one implementation of the method, the passivation pattern has: a first pattern portion having the same height as a height of the nitride semiconductor structure; and a second pattern portion including a plurality of column portions spaced apart from each other and positioned inwardly of the first pattern portion, wherein each of the plurality of column portions has a height smaller than the height of the first pattern portion, and extends through the undoped semiconductor layer and into the first semiconductor layer.

A fourth aspect of the present disclosure provides a method for manufacturing a light-emitting device, the method comprising: forming a plurality of body portions of a passivation pattern on a growth substrate so as to be spaced apart from each other via a first space; sequentially forming an undoped semiconductor layer and a lower portion of the first semiconductor layer in the first space; forming a head portion on the body portion of the passivation pattern so as to have a smaller width than a width of the body portion, such that a second space having a width larger than a width of the first space is defined between adjacent head portions; sequentially forming an upper portion of the first semiconductor layer, an active layer, and the second semiconductor layer on the lower portion of the first semiconductor layer and in the second space, thereby forming adjacent nitride semiconductor structures; exposing a portion of an upper surface of the head portion of the passivation pattern; etching the exposed portion of the upper surface of the head portion of the passivation pattern until a surface of the growth substrate is exposed, thereby spacing the adjacent nitride semiconductor structures from each other; and removing the growth substrate from the nitride semiconductor structures.

In one implementation of the method, the passivation pattern includes an insulating material on which nitride semiconductor does not grow.

In one implementation of the method, spacing adjacent nitride semiconductor structures from each other is performed such that a remaining portion of the passivation pattern after the etching thereof surrounds an outer side surface of the nitride semiconductor structure.

In one implementation of the method, the passivation pattern is etched in a dry etching scheme using plasma.

According to the aspects and the implementations of the present disclosure, the dry etching process can be performed while the passivation pattern surrounds the outer side surface of the nitride semiconductor structure. Thus, the nitride semiconductor structure can be prevented from being damaged by plasma.

Accordingly, the occurrence of the abnormal combination of electrons and holes that do not participate in light emission due to the plasma-induced damage to the nitride semiconductor structure can be suppressed or minimized, such that the light-emitting efficiency can be prevented from being reduced.

Further, the pad electrodes are formed while the passivation pattern surrounds the outer side surface of the nitride semiconductor structure. Thus, at least a portion of the pad electrode can overlap the passivation pattern, thereby increasing the light-emitting area.

Further, the pad electrodes are formed in a state in which the passivation pattern is pre-formed. Thus, an additional etching process for forming a pad electrode open area can be omitted, and thus a manufacturing yield of the light-emitting element can be improved.

Further, the passivation pattern that can pre-specify the position where the nitride semiconductor structure is to be formed is formed on the growth substrate. Thus, subsequently, the nitride semiconductor structure can be easily formed.

In addition, the passivation pattern can be formed so as to minimize the contact area between the growth substrate and the nitride semiconductor layer in the epitaxy process for forming the nitride semiconductor structure. Thus, the quality of the nitride semiconductor layer can be improved.

In addition, the passivation pattern can be formed so as to implement a shape of the nitride semiconductor structure to achieve the current confinement, thereby improving current injection efficiency.

Effects of the present disclosure are not limited to the effects mentioned above, and other effects not mentioned will be clearly understood by those skilled in the art from the descriptions below.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIGS. 1A to 1E are diagrams for illustrating a method for manufacturing a light-emitting element according to a first embodiment of the present disclosure.

FIG. 2 is a plan view of the light-emitting element according to the first embodiment.

FIG. 3 is a graph showing a percentage of non-light-emitting combination based on a size of a micro-LED.

FIG. 4 is a graph showing light-emitting efficiency based on the size of the micro-LED in FIG. 3.

FIG. 5A and FIG. 5B are diagrams for illustrating a light-emitting element according to a second embodiment of the present disclosure.

FIG. 6 is a diagram for illustrating a light-emitting element according to a third embodiment of the present disclosure.

FIG. 7 is a diagram for illustrating a light-emitting element according to a fourth embodiment of the present disclosure.

FIG. 8 is a diagram for illustrating a light-emitting element according to a fifth embodiment of the present disclosure.

FIG. 9A and FIG. 9B are diagrams for illustrating a light-emitting element according to a sixth embodiment of the present disclosure.

FIGS. 10A and 10B are diagrams for illustrating a light-emitting element according to a seventh embodiment of the present disclosure.

FIG. 11A is a diagram for illustrating a light-emitting element according to an eighth embodiment of the present disclosure.

FIG. 11B is a diagram for illustrating light-emitting efficiency of the light-emitting element according to the eighth embodiment of the present disclosure.

FIG. 12 is a diagram for illustrating a passivation pattern according to an embodiment of the present disclosure.

FIG. 13A to FIG. 13H are cross-sectional views illustrating a method for manufacturing the light-emitting element according to the second embodiment of the present disclosure.

FIG. 14A to FIG. 14G are cross-sectional views illustrating a method for manufacturing the light-emitting element according to the third embodiment of the present disclosure.

FIG. 15A to FIG. 15D are cross-sectional views illustrating a method for manufacturing the light-emitting element according to the fourth embodiment of the present disclosure.

FIG. 16A to FIG. 16E are cross-sectional views illustrating a method for manufacturing the light-emitting element according to the fifth embodiment of the present disclosure.

FIG. 17A to FIG. 17F are cross-sectional views illustrating a method for manufacturing the light-emitting element according to the sixth embodiment of the present disclosure.

FIG. 18A to FIG. 18D are cross-sectional views illustrating a method for manufacturing the light-emitting element according to the seventh embodiment of the present disclosure.

FIG. 19A to FIG. 19F are cross-sectional views illustrating a method for manufacturing the light-emitting element according to the eighth embodiment of the present disclosure.

### DETAILED DESCRIPTION OF THE EMBODIMENTS

Advantages and features of the present disclosure, and a method of achieving the advantages and features will become apparent with reference to embodiments described later in detail together with the accompanying drawings. However, the present disclosure is not limited to the embodiments as disclosed under, but can be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto. The same reference numerals refer to the same elements herein.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements can denote the entire list of elements, can denote the individual elements of the list, or can denote any combination of the elements of the list. In interpretation of numerical values, an error or tolerance therein can occur even when there is no explicit description thereof.

In addition, it will also be understood that when a first element or layer is referred to as being present “on” a second element or layer, the first element can be disposed directly on the second element or can be disposed indirectly on the second element with a third element or layer being disposed between the first and second elements or layers. It will be understood that when an element or layer is referred to as being “connected to”, or “coupled to” another element or layer, it can be directly on, connected to, or coupled to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

Further, as used herein, when a layer, film, region, plate, or the like is disposed “on,” “over,” “above,” or “on a top” of another layer, film, region, plate, or the like, the former can directly contact the latter or still additional layer(s), film(s), region(s), plate(s), or the like can be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former can directly contact the latter or still additional layer(s), film(s), region(s), plate(s), or the like can be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is indicated.

When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms “first”, “second”, “third”, and so on can be used herein to describe various elements, components, regions, layers and/or sections, these elements, components, regions, layers and/or sections should not be limited by these terms. These terms are used to distinguish one element, component, region, layer or section from another element, component, region, layer or section, and may not define any order or sequence. Thus, a first element, component, region, layer or section described below could be termed a second element, component, region, layer or section, without departing from the spirit and scope of the present disclosure.

The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects,” and the like should not be construed such that any aspect or design as described is superior to or advantageous over other aspects or designs.

Further, the term ‘or’ means ‘inclusive or’ rather than ‘exclusive or’. For example, unless otherwise stated or clear from the context, the expression that ‘x uses a or b’ preferably means any one of natural inclusive permutations.

The terms used in the description below have been selected as being general and universal in the related technical field. However, there can be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term can be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

Hereinafter, a light-emitting element according to various embodiments of the present disclosure will be described with reference to the accompanying drawings. All the components of each light-emitting element and any device that utilizes such element according to all embodiments of the present disclosure are operatively coupled and configured.

Further, any and each light-emitting element (or light-emitting device) according to all embodiments of the present disclosure can be utilized in various devices including, but not limited to, a display device such as a micro-LED display device or an organic light-emitting display device, a lighting device, an illumination device, etc.

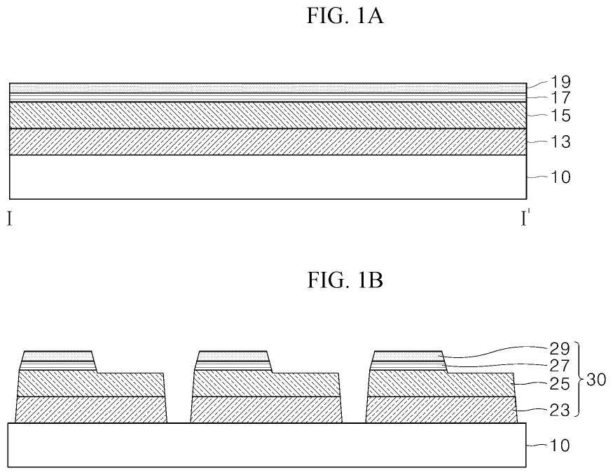

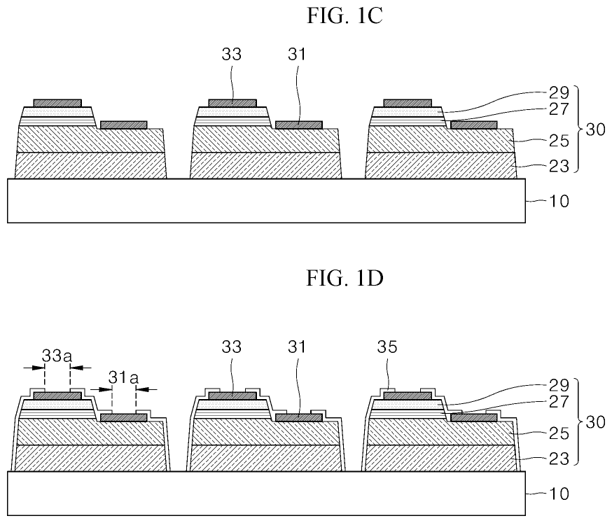

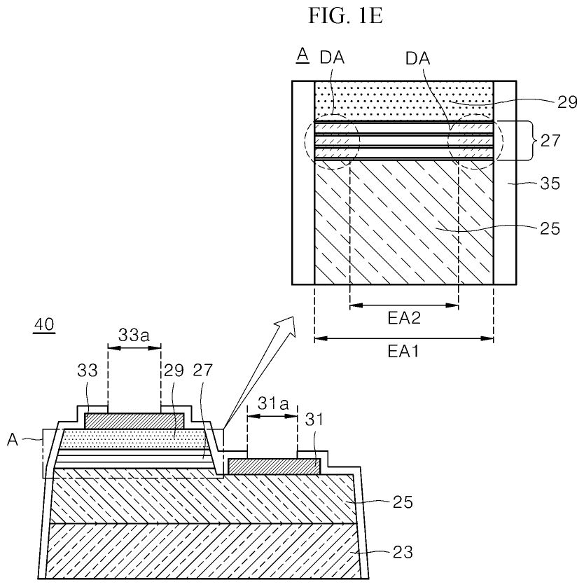

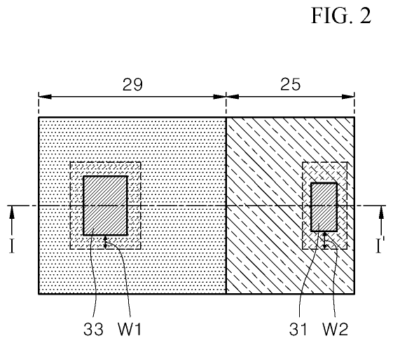

FIGS. 1A to 1E are diagrams for illustrating a method for manufacturing a light-emitting element according to a first embodiment of the present disclosure. FIG. 2 is a plan view of the light-emitting element according to the first embodiment.

Referring to FIG. 1A, an undoped semiconductor material layer 13, a first semiconductor material layer 15, an active material layer 17, and a second semiconductor material layer 19 are sequentially stacked on a growth substrate 10. In this regard, FIG. 1A is a cross-sectional view taken along a line I-I′ of FIG. 2.

The growth substrate 10 can include a material such as sapphire, silicon (Si), silicon carbide (SiC) or gallium arsenide (GaAs). However, the present disclosure is not limited thereto. The undoped semiconductor material layer 13 can include an undoped nitride semiconductor. For example, the nitride semiconductor can be made of a GaN-based semiconductor material.

The first semiconductor material layer 15 can be formed on the undoped semiconductor material layer 13 and include a nitride semiconductor containing first conductivity-type impurities. For example, the first conductivity-type impurities can include N-type impurities. The nitride semiconductor can be made of a GaN-based semiconductor material including GaN, AlGaN, InGaN, or AlInGaN. The N-type impurities contained in the first semiconductor material layer 15 can include silicon (Si), germanium (Ge), tellurium (Te), selenium (Se) or carbon (C).

The active material layer 17 is formed on the first semiconductor material layer 15. The active material layer 17 is a layer for emitting light, and can have a multi-quantum well (MQW) structure having a well layer and a barrier layer having a higher band gap than that of the well layer. For example, the active material layer 17 can be composed of an InGaN layer as the well layer and an AlGaN layer as the barrier layer.

The second semiconductor material layer 19 is formed on the active material layer 17. The second semiconductor material layer 19 can include a nitride semiconductor containing second conductivity-type impurities. For example, the second conductivity-type impurities can include P-type impurities. The nitride semiconductor can be made of a GaN-based semiconductor material including GaN, AlGaN, InGaN, or AlInGaN. The P-type impurities contained in the second semiconductor material layer 19 can include manganese (Mg), zinc (Zn), or beryllium (Be). In one example, in the present disclosure, an example in which the first semiconductor material layer 15 and the second semiconductor material layer 19 are made of the nitride semiconductor containing the N-type impurities and the nitride semiconductor including the P-type impurities, respectively is described. However, the present disclosure is not limited thereto. In another example, the first semiconductor material layer 15 and the second semiconductor material layer 19 can be made of a nitride semiconductor containing the P-type impurities and a nitride semiconductor containing the N-type impurities, respectively.

Referring to FIG. 1B, the second semiconductor material layer 19, the active material layer 17, the first semiconductor material layer 15, and the undoped semiconductor material layer 13 are patterned to form nitride semiconductor structures 30 disposed on the growth substrate 10 so as to be spaced apart from each other.

Each of the patterned nitride semiconductor structures 30 can include an undoped semiconductor layer 23, a first semiconductor layer 25, an active layer 27, and a second semiconductor layer 29. In this regard, the patterning process can be performed in a mesa etching manner to expose a portion of a surface of the first semiconductor layer 25. Such mesa etching can be performed in a dry etching scheme. The dry etching scheme can be carried out using an inductively coupled plasma-reactive ion etch (ICP-RIE) using reactive gas.

However, in performing the patterning process in the dry etching scheme, damage can occur on each of both opposing side surfaces of the nitride semiconductor structure 30, resulting in decrease in light-emitting efficiency. A detailed description thereof will be made later.

Referring to FIG. 1C, an electrode material layer is formed on the nitride semiconductor structure 30 and then is patterned, such that a first electrode 31 is formed on a surface of the first semiconductor layer 25 exposed by performing the mesa etching, while a second electrode 33 is formed on the second semiconductor layer 29. Each of the first electrode 31 and the second electrode 33 can be made of at least one metal of, for example, Au, W, Pt, Ir, Ag, Cu, Ni, (Ti), (Cr), or an alloy thereof. Alternatively, each of the first electrode 31 and the second electrode 33 can include a transparent metal oxide such as indium-tin-oxide (ITO) or indium-zinc-oxide (IZO).

Referring to FIG. 1D, a passivation layer is formed on the nitride semiconductor structure 30 and an etching process is performed thereon. Thus, a passivation pattern 35 having open areas 31a and 33a defined therein in which the first electrode 31 and the second electrode 33 are partially exposed is formed. The passivation pattern 35 can be formed to cover a portion of a surface of an edge of each of the first electrode 31 and the second electrode 33 while covering an outer side surface of the nitride semiconductor structure 30.

The passivation pattern 35 serves to prevent any damaged portions from occurring on both opposing side surfaces of the nitride semiconductor structure 30 during the dry etching process to form the nitride semiconductor structure 30 of FIG. 1B.

The growth substrate 10 is then removed from the nitride semiconductor structure 30 and then a plurality of individual light-emitting element structures 40 are obtained in a separated manner. A single individual light-emitting element structure 40 is as shown in FIG. 1E. In this regard, the growth substrate 10 can be removed therefrom in a laser lift off (LLO) manner. Further, an enlarged view of a region A of the light-emitting structure 40 is shown in the top drawing of FIG. 1E.

In one example, when the dry etching using the inductively coupled plasma is performed in a state in which the undoped semiconductor material layer 13, the first semiconductor material layer 15, the active material layer 17, and the second semiconductor material layer 19 are stacked, as shown in FIG. 1B, damage by the plasma can occur on both opposing side surfaces of the light-emitting element structure 40, which is shown as damaged areas DA in the region A of FIG. 1E.

Specifically, when the plasma is applied to the stack in which the undoped semiconductor material layer 13, the first semiconductor material layer 15, the active material layer 17, and the second semiconductor material layer 19 are stacked, the first semiconductor material layer 15, the active material layer 17, and the second semiconductor material layer 19 are directly exposed to plasma, such that an intermolecular bond can be broken and thus a carrier trap site can be created. However, this carrier trap site can be unstable and thus, many non-light-emitting combinations of electron-holes that do not participate in light emission can occur at this site.

Since a micro-LED has a size smaller than 100 micrometers (μm), a percentage of a size of a sidewall area where many of these non-light-emitting combinations occur relative to a total area size of the micro-LED can be relatively large. Accordingly, upon application of the same current thereto, the light-emitting efficiency may be largely reduced.

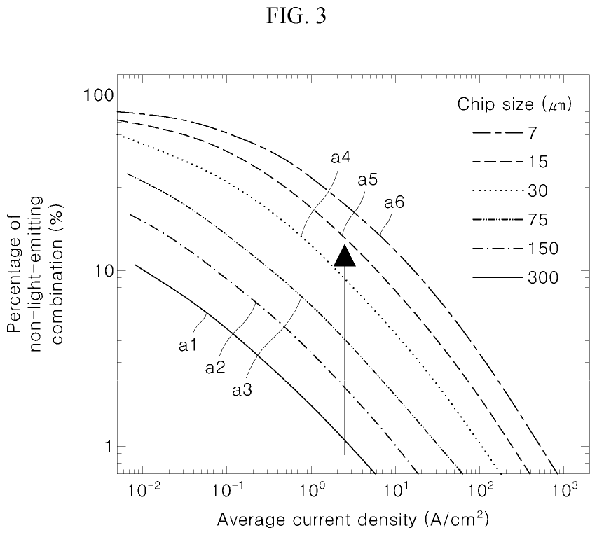

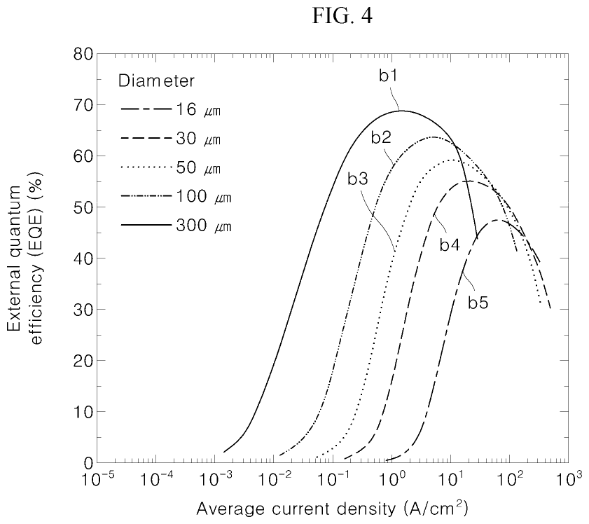

FIG. 3 is a graph showing an example of a percentage of non-light-emitting combination based on a size of a micro-LED. FIG. 4 is a graph showing light-emitting efficiency based on the size of the micro-LED in FIG. 3.

Referring to FIG. 3, it can be seen that as a size of a micro-LED chip becomes smaller, that is, the size of the micro-LED chip changes from 300 μm (a1) to 150 μm (a2) to 75 μm (a3) to 30 μm (a4) to 15 μm (a5) to 7 μm (a6), a percentage (%) of the non-light-emitting combination increases as indicated by an arrow direction. Thus, it can be seen as shown in FIG. 4 that as the size of the micro-LED chip becomes smaller, that is, the size of the micro-LED chip changes from 300 μm (b1) to 100 μm (b2) to 50 μm (b3) to 30 μm (b4) to 16 μm (b5) to 7 μm (b6), external quantum efficiency (EQE) decreases because the percentage (%) of the non-light-emitting combination increases.

Accordingly, referring back to FIG. 1E, a target size of the light-emitting area is ‘EA1’. However, a number of abnormal combinations of electrons and holes that do not participate in light emission can occur on each of both opposing side surfaces of the light-emitting element structure 40 due to the plasma damage. Thus, the size of the light-emitting area can be reduced by the size of the damaged area DA from each of the opposing side surfaces. Thus, an actual size (effective size) of the light-emitting area becomes ‘EA2’, which is smaller than the target light-emitting area size EA1. Thus, on application of the same current thereto, luminance in the damaged area DA is relatively lower than the luminance in the actual light-emitting area EA2, and the light-emitting efficiency can be largely reduced.

Further, referring to FIG. 2, the first electrode 31 is formed such that the entire lower surface thereof contacts the first semiconductor layer 25, while the second electrode 33 is formed such that the entire lower surface contacts the second semiconductor layer 29. Accordingly, the light-emitting efficiency of the light-emitting area can decrease by the contact area of the first electrode 31 and the second electrode 33 with the nitride semiconductor structure 30. The first electrode 31 or the second electrode 33 can be composed of a transparent electrode including a transparent metal oxide such as indium-tin-oxide (ITO) or indium-zinc-oxide (IZO). In one example, transparency of indium-tin-oxide (ITO) can change depending on a heat treatment condition thereon. However, even when the first electrode 31 or the second electrode 33 is composed of the transparent electrode including the transparent metal oxide such as such as indium-tin-oxide (ITO), a shaded area can occur in an area in which the first electrode 31 or the second electrode 33 overlaps the first semiconductor layer 25 or the second semiconductor layer 29. Thus, relatively large power consumption can be needed to realize target brightness in the shaded area, which in turn lowers the light-emitting efficiency.

In other words, the light-emitting efficiency of the light-emitting area can be reduced by the size of the area where each of the first and second electrodes 31 and 33 overlaps a corresponding one of the first and second semiconductor layers 25 and 29. In particular, since the size of the micro-LED can be smaller than 100 micrometers (μm), the size of the area where the shaded area occurs can be relatively large relative to the total area size. Accordingly, the light-emitting efficiency can decrease upon application of the same current.

In addition, after the nitride semiconductor structure 30 is formed, the passivation layer is formed thereon, and the etching process is performed thereon to form the open areas 31a and 33a for partially exposing the first electrode 31 and the second electrode 33, respectively. Thus, an additional process for forming the open areas 31a and 33a inevitably occurs. As such, a manufacturing yield of the light-emitting element can be reduced due to an alignment defect that can occur during the additional process. In addition, the first electrode 31 and the second electrode 33 are covered with the passivation pattern 35 by a second width W2 and a first width W1, respectively, as shown in FIG. 2.

To address these issues discussed above, in another embodiment of the present disclosure, a light-emitting element capable of preventing the increase in abnormal combinations of electron-holes that do not participate in light emission and capable of increasing light-emitting efficiency, and a method for manufacturing such light-emitting element will now be described below. The present disclosure will be described with reference to the drawings below.

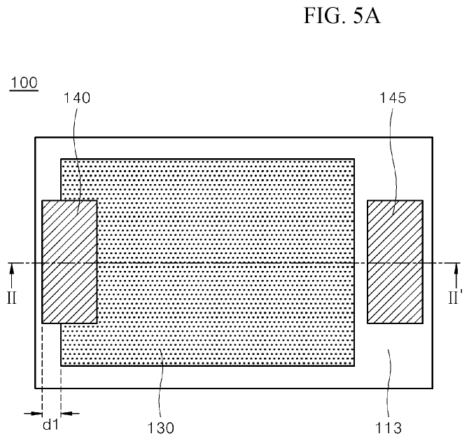

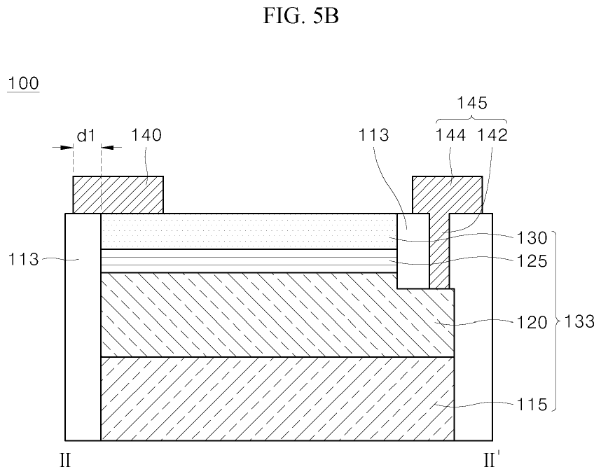

FIG. 5A and FIG. 5B are diagrams for illustrating a light-emitting element according to a second embodiment of the present disclosure. In this regard, FIG. 5B is a cross-sectional view cut along a line II-II′ of FIG. 5A. A description of at least some of the features in the second embodiment can be the same as or similar to that of the first embodiment and as such, the description of some of such features may be omitted or may be briefly provided.

Referring to FIGS. 5A and 5B, a light-emitting element 100 according to the second embodiment of the present disclosure can include an undoped semiconductor layer 115, a first semiconductor layer 120, an active layer 125, a second semiconductor layer 130, a first electrode 145, a second electrode 140, and a passivation pattern 113.

A nitride semiconductor structure 133 can include the undoped semiconductor layer 115, the first semiconductor layer 120, the active layer 125, and the second semiconductor layer 130. At one side of the nitride semiconductor structure 133, the undoped semiconductor layer 115, the first semiconductor layer 120, the active layer 125, and the second semiconductor layer 130 are sequentially stacked such that a step is not formed, while at the other side thereof, the undoped semiconductor layer 115, the first semiconductor layer 120, the active layer 125, and the second semiconductor layer 130 are sequentially stacked such that a width of each of the active layer 125 and the second semiconductor layer 130 is relatively smaller than that of the undoped semiconductor layer 115 and thus a step is formed. That is, at the other side of the nitride semiconductor structure 133, a portion of a top surface of the first semiconductor layer 120 can be exposed such that the step is formed at the top surface thereof.

The passivation pattern 113 can have a shape surrounding an outer side surface of the nitride semiconductor structure 133. Accordingly, the nitride semiconductor structure 133 can have an isolated shape due to the passivation pattern 113. An upper surface of the passivation pattern 113 can be coplanar with an upper surface of the second semiconductor layer 130.

The first electrode 145 and/or the second electrode 140 can be disposed in an overlapping manner with at least a portion of the passivation pattern 113. For example, the first electrode 145 can include a column portion 142 that extends through the passivation pattern 113 so as to contact the first semiconductor layer 120, and a head portion 144 extending from the column portion 142 and disposed on the upper surface of the passivation pattern 113. Further, at least a portion of the second electrode 140 overlaps the upper surface of the passivation pattern 113.

Accordingly, at least a majority or some of the first electrode 145 can be prevented from directing contacting or overlapping with the first semiconductor layer 120, thereby preventing occurrence of a shaded area in a light-emitting area of the light-emitting element 100. In addition, the occurrence of the shaded area in the light-emitting area can be prevented by a size of an area where the second electrode 140 overlaps with the passivation pattern 113. Accordingly, light-emitting efficiency in the light-emitting area of the light-emitting element 100 can increase by the size of the area where the second electrode 140 overlaps the passivation pattern 113. Further, as the upper surface of the passivation pattern 113 is coplanar with the upper surface of the second semiconductor layer 130, the first electrode 145 and/or the second electrode 140 can have an exposed upper surface and an exposed side surface.

The light-emitting element 100 according to the second embodiment of the present disclosure can have a lateral-type structure having a mesa structure.

The first electrode 145 and/or the second electrode 140 can be composed of a single layer or multiple layers made of a conductive material such as titanium (Ti), chromium (Cr), aluminum (Al), or gold (Au).

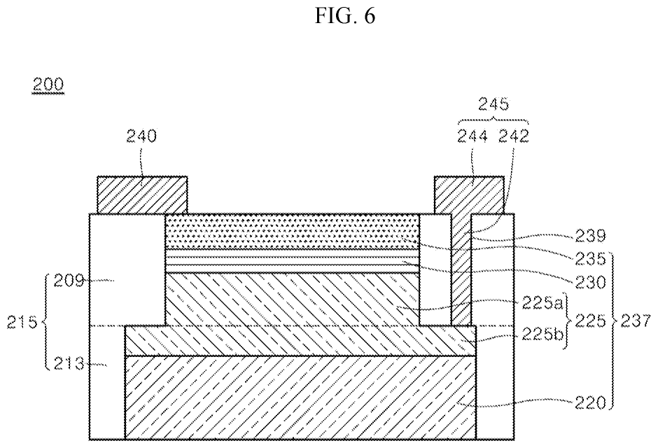

FIG. 6 is a diagram for illustrating a light-emitting element according to a third embodiment of the present disclosure. The light-emitting element of FIG. 6 shows a cross-section view of a light-emitting element 200, similar to that of FIG. 5B, but according to the third embodiment.

Referring to FIG. 6, the light-emitting element 200 according to the third embodiment of the present disclosure can include a nitride semiconductor structure 237 acting as a light-emitting layer, a passivation pattern 215 surrounding the entirety of an outer side surface of the nitride semiconductor structure 237, and a first electrode 245 and a second electrode 240.

The nitride semiconductor structure 237 can include an undoped semiconductor layer 220, a first semiconductor layer 225, an active layer 230, and a second semiconductor layer 235. In the nitride semiconductor structure 237, a width of each of the active layer 230 and the second semiconductor layer 235 is smaller than that of the undoped semiconductor layer 220. Further, the first semiconductor layer 225 has a step. In this regard, the first semiconductor layer 225 can include an upper portion 225a having the same width as that of each of the active layer 230 and the second semiconductor layer 235, and a lower portion 225b having the same width as that of the undoped semiconductor layer 220. The lower portion 225b of the first semiconductor layer 225 can be formed to have a relatively larger width than that of the upper portion 225a such that the lower portion 225b of the first semiconductor layer 225 can protrude outwardly beyond a sidewall of the upper portion 225a and have an exposed upper surface at each of both opposing sides thereof. Accordingly, the nitride semiconductor structure 237 can have an ‘inverted-T’ shape in a cross-sectional view as shown in FIG. 6.

The passivation pattern 215 can surround the entirety of the outer side surface of the nitride semiconductor structure 237 and can include an insulating material. The passivation pattern 215 can include a head portion 209 surrounding a sidewall of each of the second semiconductor layer 235, the active layer 230, the upper portion 225a of the first semiconductor layer 225; and a column portion 213 surrounding a sidewall of the lower portion 225b of the first semiconductor layer 225, and a sidewall of the undoped semiconductor layer 220. The head portion 209 and the column portion 213 of the passivation pattern 215 can be made of the same material.

The passivation pattern 215 can further include a contact hole 239 extending through the head portion 209 so as to expose a portion of an upper surface of the lower portion 225b of the first semiconductor layer 225 at one side of the nitride semiconductor structure 237.

Each of the first electrode 245 and the second electrode 240 can be disposed in an overlapping manner with at least a portion of the passivation pattern 215. Specifically, the first electrode 245 can include a column portion 242 filling the contact hole 239 extending through the head portion 209 of the passivation pattern 215 and contacting an exposed upper surface of a horizontally and outwardly protruding portion of the lower portion 225b of the first semiconductor layer 225, and a head portion 244 disposed on the upper surface of the passivation pattern 215. The second electrode 240 disposed on the second semiconductor layer 235 so as to be spaced apart from the first electrode 245 is positioned so that at least a portion of a lower surface thereof contacts and overlaps with the upper surface of the passivation pattern 215. Accordingly, the light-emitting area of the light-emitting element 200 can increase by a size of the area where the second electrode 240 overlaps with the head portion 209 of the passivation pattern 215.

As the upper surface of the passivation pattern 215 is coplanar with the upper surface of the second semiconductor layer 235, the first electrode 245 and/or the second electrode 240 can have an exposed upper surface and an exposed side surface.

The first electrode 245 and/or the second electrode 240 can be composed of a single layer or multiple layers made of a conductive material such as titanium (Ti), chromium (Cr), aluminum (Al), or gold (Au).

The light-emitting element 200 according to the third embodiment of the present disclosure can have a lateral-type structure having a mesa structure/shape.

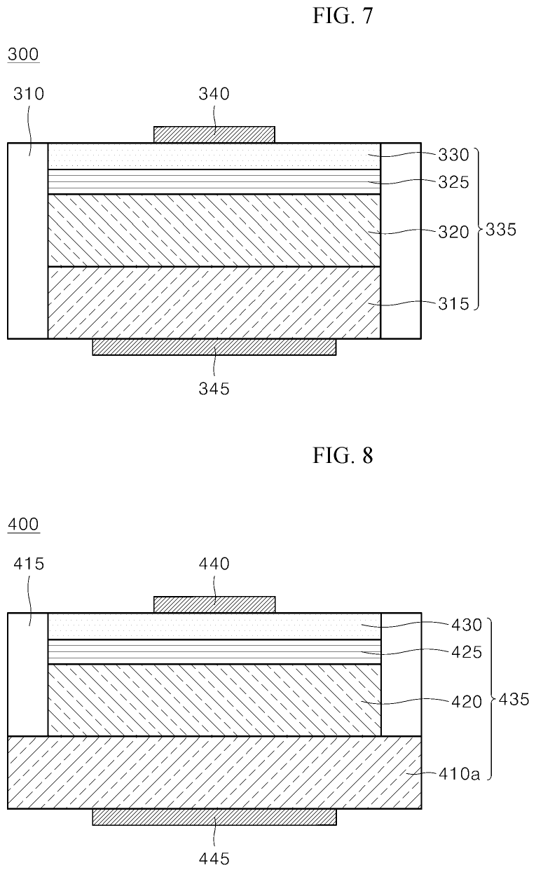

FIG. 7 is a diagram for illustrating a light-emitting element according to a fourth embodiment of the present disclosure. The light-emitting element of FIG. 6 shows a cross-section view of the light-emitting element according to the fourth embodiment.

Referring to FIG. 7, a light-emitting element 300 according to the fourth embodiment of the present disclosure can include a nitride semiconductor structure 335, a passivation pattern 310 surrounding an outer side surface of the nitride semiconductor structure 335, a first electrode 345, and a second electrode 340. The nitride semiconductor structure 335 can include an undoped semiconductor layer 315, a first semiconductor layer 320, an active layer 325, and a second semiconductor layer 330. The nitride semiconductor structure 335 can have a vertical-type structure in which the undoped semiconductor layer 315, the first semiconductor layer 320, the active layer 325, and the second semiconductor layer 330 are sequentially and vertically stacked.

The nitride semiconductor structure 335 can have the same width as each of a width of the undoped semiconductor layer 315 positioned at the lowest level, and a width of the second semiconductor layer 330 positioned at a topmost level. Accordingly, the nitride semiconductor structure 335 can have a rectangular shape in a cross-sectional view as shown in FIG. 7.

The passivation pattern 310 can surround the entirety of the outer side surface of the nitride semiconductor structure 335 and can be made of a material that suppresses semiconductor layer growth, for example, an insulating material. The upper surface of the passivation pattern 310 can be coplanar with the upper surface of the second semiconductor layer 330, while a lower surface of the passivation pattern 310 can be coplanar with a lower surface of the undoped semiconductor layer 315.

The first electrode 345 is disposed on (i.e., below or under) the lower surface of the undoped semiconductor layer 315 and is electrically connected to the first semiconductor layer 320, while the second electrode 340 is disposed on the upper surface of the second semiconductor layer 330 and is electrically connected thereto.

FIG. 8 is a diagram for illustrating a light-emitting element according to a fifth embodiment of the present disclosure. The light-emitting element of FIG. 8 is different from the light-emitting element of FIG. 7 in terms of a thickness of each of the light-emitting element and the passivation patter, and other components of FIG. 8 are the same as or similar to those of FIG. 7 and thus will be briefly described.

Referring to FIG. 8, a light-emitting element 400 can include an undoped semiconductor layer 410a, a first semiconductor layer 420, an active layer 425, a second semiconductor layer 430 sequentially stacked on the undoped semiconductor layer 410a, a first electrode 445, a second electrode 440 and a passivation pattern 415.

The nitride semiconductor structure 435 can include the undoped semiconductor layer 410a, the first semiconductor layer 420, the active layer 425, and the second semiconductor layer 430. Both opposing side surfaces of the first semiconductor layer 420, the active layer 425, and the second semiconductor layer 430 respectively are aligned with each other in a line.

In this regard, the undoped semiconductor layer 410a positioned at the lowermost level of the nitride semiconductor structure 435 can protrude outwardly beyond the outer side surfaces of the first semiconductor layer 420, the active layer 425, and the second semiconductor layer 430 and thus can have a relatively larger width. Accordingly, a portion of an upper surface of the undoped semiconductor layer 410a can be exposed. Thus, the nitride semiconductor structure 435 can have an ‘inverted-T’ shape in a cross-sectional view as shown in FIG. 8.

The passivation pattern 415 can be disposed on the exposed upper surface of the protruding portion of the undoped semiconductor layer 410a and can surround the side surfaces of the first semiconductor layer 420, the active layer 425, and the second semiconductor layer 430.

An upper surface of the passivation pattern 415 is coplanar with an upper surface of the second semiconductor layer 430. The first electrode 445 is disposed on (i.e., under or beneath) the lower surface of the undoped semiconductor layer 410a and is electrically connected to the first semiconductor layer 420, while the second electrode 440 is disposed on the second semiconductor layer 430 and is electrically connected thereto.

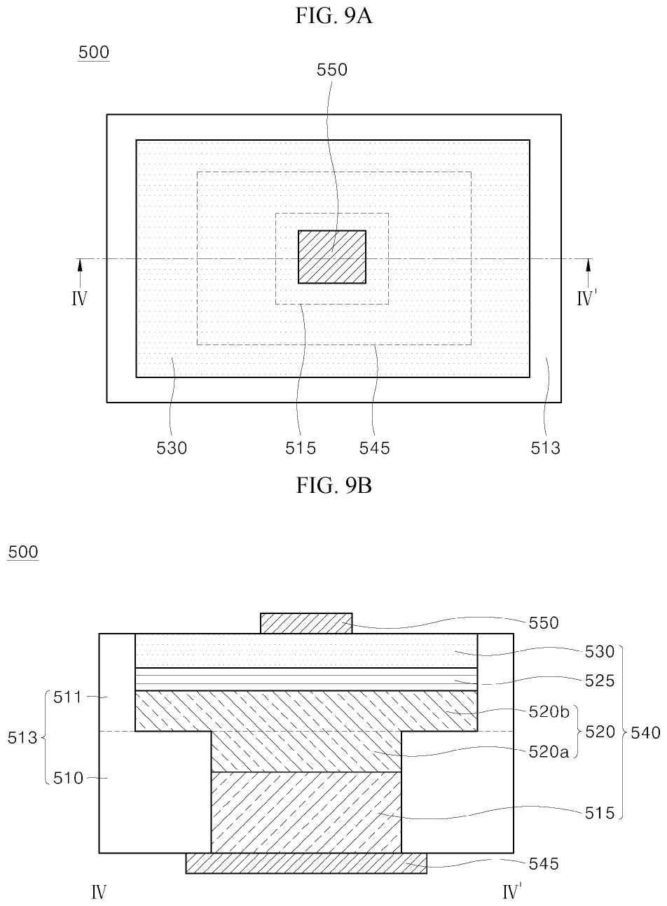

FIG. 9A and FIG. 9B are diagrams for illustrating a light-emitting element according to a sixth embodiment of the present disclosure. In this regard, FIG. 9B is a cross-sectional view cut along a line IV-IV′ of FIG. 9A.

Referring to FIG. 9A and FIG. 9B, a light-emitting element 500 can include an undoped semiconductor layer 515, a first semiconductor layer 520, an active layer 525, a second semiconductor layer 530, a first electrode 545, a second electrode 550, and a passivation pattern 513. Here the second electrode 550, the undoped semiconductor layer 515, the second electrode 545 and the second semiconductor layer 530 are disposed in a concentric configuration.

A nitride semiconductor structure 540 can include the undoped semiconductor layer 515, the first semiconductor layer 520, the active layer 525, and the second semiconductor layer 530. In the nitride semiconductor structure 540, both opposing side surfaces of the second semiconductor layer 530 and the active layer 525 can be respectively aligned with each other in a line. For instance, all four sides can be aligned. Further, in the nitride semiconductor structure 540, the undoped semiconductor layer 515 can have a relatively smaller width than a width of each of the active layer 525 and the second semiconductor layer 530.

The first semiconductor layer 520 disposed between the active layer 525 and the undoped semiconductor layer 515 can have a step. For example, a lower portion 520a of the first semiconductor layer 520 disposed on top of the undoped semiconductor layer 515 can have a relatively smaller width than that of the active layer 525, while both opposing side surfaces of an upper portion 520b of the first semiconductor layer 520 contacting a lower surface of the active layer 525 and both opposing side surfaces of the active layer 525 can be aligned with each other in a line such that the upper portion 520b can have the same width as that of the active layer 525. Accordingly, referring to FIG. 9A, the nitride semiconductor structure 540 can have a ‘T’ shape in a cross-sectional view as shown, and/or in a cross-section view that is perpendicular to the current cross-section view.

The passivation pattern 513 can have a shape surrounding an outer side surface of the nitride semiconductor structure 540. Specifically, the passivation pattern 513 can include a body portion 510 surrounding an outer side surface of each of the undoped semiconductor layer 515 and the lower portion 520a of the first semiconductor layer 520, and a head portion 511 surrounding an outer side surface of each of the upper portion 520b of the first semiconductor layer 520, the active layer 525, and the second semiconductor layer 530.

An upper surface of the passivation pattern 513 can be coplanar with an upper surface of the second semiconductor layer 530 while a lower surface of the passivation pattern 513 can be coplanar with a lower surface of the undoped semiconductor layer 515. Thus, the passivation pattern 513 can have a shape surrounding the outer side surface of the nitride semiconductor structure 540.

The first electrode 545 is disposed on (i.e., below or under) the undoped semiconductor layer 515 and is electrically connected to the first semiconductor layer 520 providing electrons to the active layer 525, while the second electrode 550 is disposed on the second semiconductor layer 530 providing holes to the active layer 525 and is electrically connected to the second semiconductor layer 530. The second electrode 550 vertically overlaps the first electrode 545. However, the present disclosure is not limited thereto.

As a width of the lower surface of the undoped semiconductor layer 515 of the nitride semiconductor structure 540 is relatively smaller than a width of the upper surface of the second semiconductor layer 530 of the nitride semiconductor structure 540, current injection efficiency can be improved due to a current confinement phenomenon.

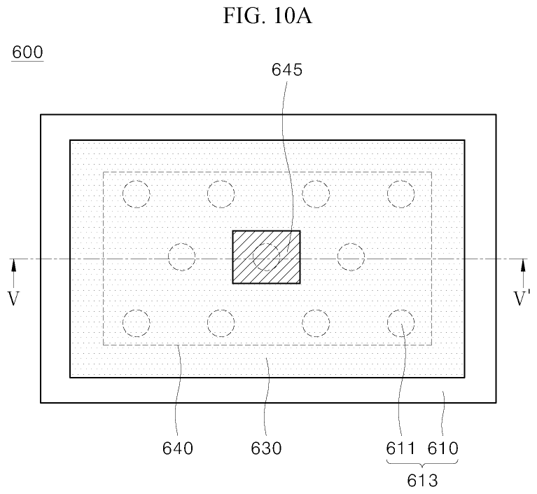

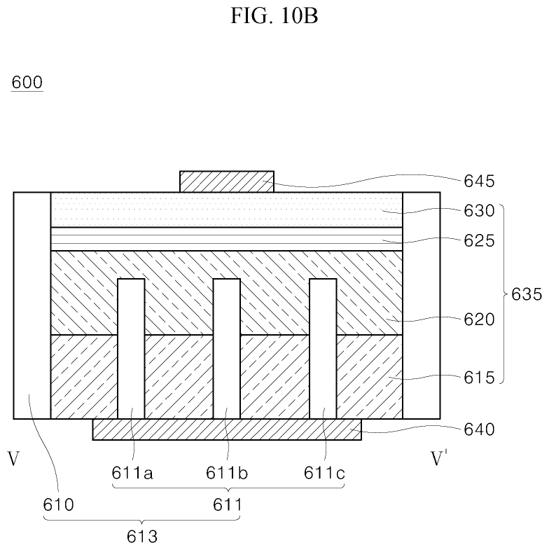

FIGS. 10A and 10B are diagrams for illustrating a light-emitting element according to a seventh embodiment of the present disclosure. In this regard, FIG. 10B is a cross-sectional view cut along a line V-V of FIG. 10A.

Referring to FIGS. 10A and 10B, a light-emitting element 600 can include a nitride semiconductor structure 635 including an undoped semiconductor layer 615, a first semiconductor layer 620, an active layer 625, and a second semiconductor layer 630, a first electrode 640, a second electrode 645, and a passivation pattern 613.

The nitride semiconductor structure 635 can have a structure in which both opposing side surfaces of the undoped semiconductor layer 615, the first semiconductor layer 620, the active layer 625, and the second semiconductor layer 630 can be respectively aligned with each other in a line.

The passivation pattern 613 can include a first pattern portion 610 and a second pattern portion 611. The passivation pattern 613 can include a non-conductive material, and in one example, can be made of an insulating material.

The first pattern portion 610 of the passivation pattern 613 can have a shape covering the outer side surface of the nitride semiconductor structure 635 having the structure in which both opposing side surfaces of the undoped semiconductor layer 615, the first semiconductor layer 620, the active layer 625, and the second semiconductor layer 630 can be respectively aligned with each other in a line. The second pattern portion 611 of the passivation pattern 613 can be positioned inwardly of the first pattern portion 610. The second pattern portion 611 can include a plurality of column portions 611a, 611b, and 611c. Neighboring column portions 611a, 611b, and 611c can be spaced apart from each other. Each of the plurality of column portions 611a, 611b, and 611c of the second pattern portion 611 can extend through the undoped semiconductor layer 615 so as to be disposed into the first semiconductor layer 620. Accordingly, the first semiconductor layer 620 can have a shape surrounding an upper surface and a portion of a side surface of each of the plurality of column portions 611a, 611b, and 611c of the second pattern portion 611 of the passivation pattern 613.

The first semiconductor layer 620 can be formed on top of the undoped semiconductor layer 615 and can include a nitride semiconductor containing first conductivity-type impurities. For example, the first conductivity-type impurities can include N-type impurities. The nitride semiconductor can be made of a GaN-based semiconductor material including GaN, AlGaN, InGaN, or AlInGaN. In one example, the N-type impurities can include silicon (Si), germanium (Ge), tellurium (Te), selenium (Se) or carbon (C).

The active layer 625 is disposed on the upper surface of the first semiconductor layer 620 and is a layer for emitting light, and can have a multi-quantum well (MQW) structure having a well layer and a barrier layer having a higher band gap than that of the well layer.

The second semiconductor layer 630 is disposed on the active layer 625. The second semiconductor layer 630 can provide holes to the active layer 625 and can be made of a nitride semiconductor that contains P-type impurities as the second conductivity-type impurities. The nitride semiconductor can be made of a GaN-based semiconductor material including GaN, AlGaN, InGaN, or AlInGaN. In one example, the P-type impurities can include manganese (Mg), zinc (Zn), or beryllium (Be).

The first electrode 640 can have a size of an area covering the entirety of the exposed surface of the second pattern portion 611 while being disposed on the lower surface of the undoped semiconductor layer 615. The second electrode 645 is disposed on the upper surface of the second semiconductor layer 630.

The light-emitting element 600 according to FIGS. 10A and 10B can be formed in a vertical-type structure. In the light-emitting element 600 according to the seventh embodiment of the present disclosure, the second pattern portion 611 of the passivation pattern 613 extends through the undoped semiconductor layer 615 so as to be disposed in the first semiconductor layer 620. Accordingly, a spacing between adjacent ones of the column portions 611a, 611b, and 611c of the second pattern portion 611 is smaller than the width of the active layer 625. The current confinement phenomenon is induced by this narrow spacing, and thus the current injection efficiency can be improved.

FIG. 11A is a diagram for illustrating a light-emitting element in a cross-section view according to an eighth embodiment of the present disclosure. FIG. 11B is a diagram for illustrating the light-emitting efficiency of the light-emitting element according to the eighth embodiment of the present disclosure.

Referring to FIG. 11A, a light-emitting element 700 includes a nitride semiconductor structure 745 including an undoped semiconductor layer 725, a first semiconductor layer 730, an active layer 735, and a second semiconductor layer 740, a first electrode 750, a second electrode 755, and a passivation pattern 720.

The nitride semiconductor structure 745 can have a structure in which a width thereof decreases as the nitride semiconductor structure 745 extends upwardly from a lower surface of the undoped semiconductor layer 725 and then a width thereof increases as the nitride semiconductor structure 745 extends upwardly toward an upper surface of the second semiconductor layer 740. In one example, the nitride semiconductor structure 745 can include an hourglass shape with a smallest width at a vertical middle level in a cross-sectional view.

The passivation pattern 720 can include a non-conductive material and, in one example, can be made of an insulating material. The passivation pattern 720 can have a shape covering an outer side surface of the nitride semiconductor structure 745. As a shape of the inner side surface of the passivation pattern 720 conforms to a shape of the outer side surface of the nitride semiconductor structure 745, the passivation pattern 720 can closely adhere to the outer side surface of the nitride semiconductor structure 745. Further, an upper surface of the passivation pattern 720 can be coplanar with an upper surface of the second semiconductor layer 740, while a lower surface of the passivation pattern 720 can be coplanar with a lower surface of the undoped semiconductor layer 725.

The first semiconductor layer 730 can be formed on top of the undoped semiconductor layer 725 and can include a nitride semiconductor containing the first conductivity-type impurities. For example, the first conductivity-type impurities can include N-type impurities. The nitride semiconductor can be made of a GaN-based semiconductor material including GaN, AlGaN, InGaN, or AlInGaN. In one example, the N-type impurities can include silicon (Si), germanium (Ge), tellurium (Te), selenium (Se) or carbon (C).

The active layer 735 can be disposed on the upper surface of the first semiconductor layer 730 and is a layer for emitting light. The active layer 735 can have a multi-quantum well (MQW) structure having a well layer and a barrier layer having a higher band gap than that of the well layer.

The second semiconductor layer 740 is disposed on the active layer 735. The second semiconductor layer 740 can provide holes to the active layer 735 and can be made of a nitride semiconductor that contains P-type impurities as the second conductivity-type impurities. The nitride semiconductor can be made of a GaN-based semiconductor material including GaN, AlGaN, InGaN, or AlInGaN. In one example, the P-type impurities could include manganese (Mg), zinc (Zn), or beryllium (Be).

The first electrode 750 can be disposed on (e.g., under or below) the lower surface of the undoped semiconductor layer 725 and can be electrically connected to the first semiconductor layer 730, while the second electrode 755 can be disposed on the upper surface of the second semiconductor layer 740 and can be electrically connected to the second semiconductor layer 740.

In the light-emitting element 700 according to FIG. 11A of the present disclosure, the outer side surface of the nitride semiconductor structure 745 has negative and positive slopes intersecting each other. The nitride semiconductor structure 745 has a polygonal shape in a cross-sectional view. The polygonal cross section thereof can allow the light emitting efficiency to be improved. For example, if the outer side surfaces of the undoped semiconductor layer 725, the first semiconductor layer 730, the active layer 735, and the second semiconductor layer 740 of the nitride semiconductor structure 745 are aligned with each other in a line and thus the nitride semiconductor structure 745 has a rectangular shape in a cross sectional view, travel paths of light are parallel to each other, the light can be trapped inside the nitride semiconductor structure.

In contrast thereto, the outer side surface of the nitride semiconductor structure 745 of the light-emitting element 700 according to FIG. 11A of the present disclosure has negative and positive slopes intersecting each other. In the cross-sectional view, the nitride semiconductor structure 745 has the polygonal shape. Thus, as the light continues to encounter different interfaces, an angle of incidence thereto continues to change, as shown by an arrow in FIG. 11B. Thus, a light amount emitted to the outside can increase such that the light extraction efficiency can be improved.

In one example, damage may occur to both opposing side surfaces of the light-emitting element structure in the process of performing dry etching to form the light-emitting element structure. Accordingly, in an embodiment of the present disclosure, a manufacturing method capable of preventing such damage to both opposing side surfaces of the light-emitting element structure will be described. Specifically, a passivation pattern capable of forming a shape of the light-emitting element structure can be formed, and then epitaxial growth is performed in a remaining area except for the passivation pattern. As such, the dry etching process that may cause damage to the nitride-based semiconductor can be omitted or prevented, and thus the light-emitting efficiency of the light-emitting element structure can be improved. This will be described with reference to the drawings below.

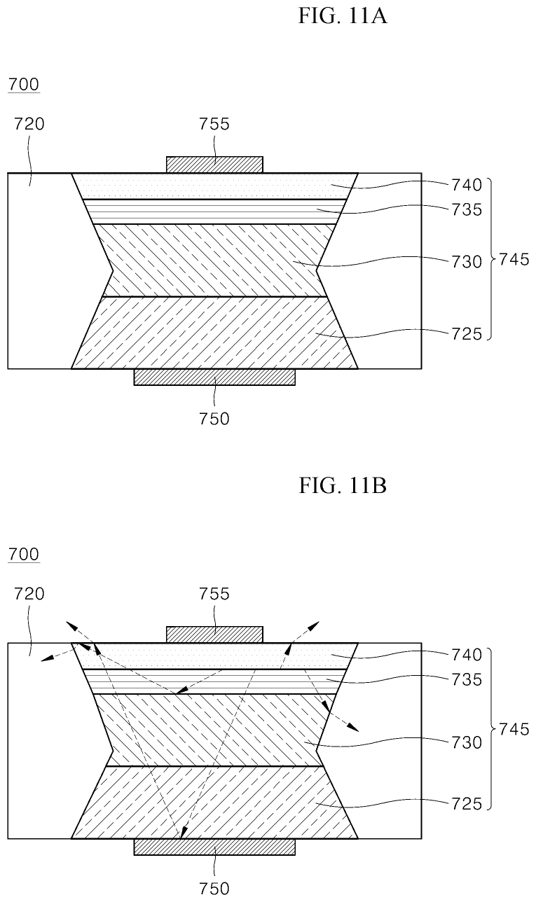

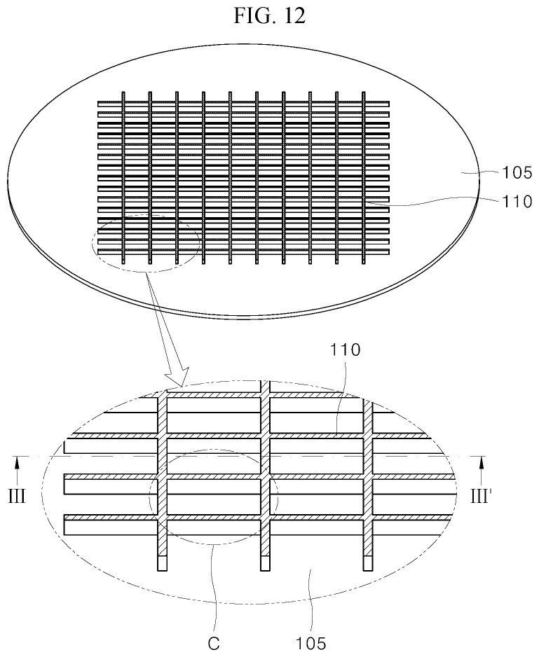

FIG. 12 is a diagram for illustrating a passivation pattern according to an embodiment of the present disclosure. This passivation pattern can be used in any suitable light-emitting element of one or more embodiments of the present disclosure, which is discussed in the present application.

Referring to FIG. 12, a body portion 110 of the passivation pattern is formed on a growth substrate 105. To this end, a passivation layer is formed on the growth substrate 105 and is patterned to form the passivation pattern. The passivation pattern can include a non-conductive material so that the nitride-based semiconductor does not grow on the passivation pattern. For example, the passivation pattern can be made of an insulating material including nitride.

The passivation pattern can have a structure in which a plurality of grid patterns are arranged such that a space is defined in each of the plurality of grid patterns. One grid pattern can have a width and a length in a range of several to several tens of micrometers (m). In this regard, one grid pattern C as shown in the enlarged view of FIG. 12 can correspond to one light-emitting element chip size. Next, the light-emitting element can be formed by performing a subsequent process in a state in which the passivation pattern has been formed on the growth substrate. Hereinafter, a method of forming each of light-emitting elements of various shapes using the above-described passivation pattern will be described.

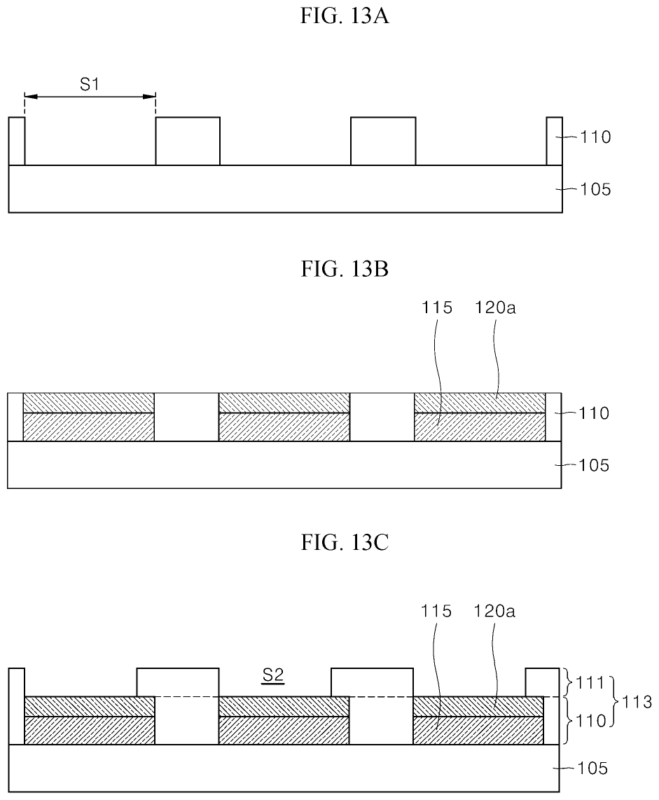

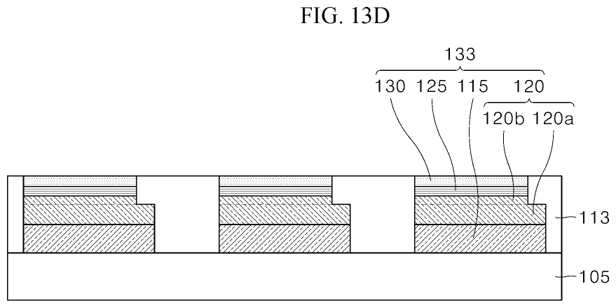

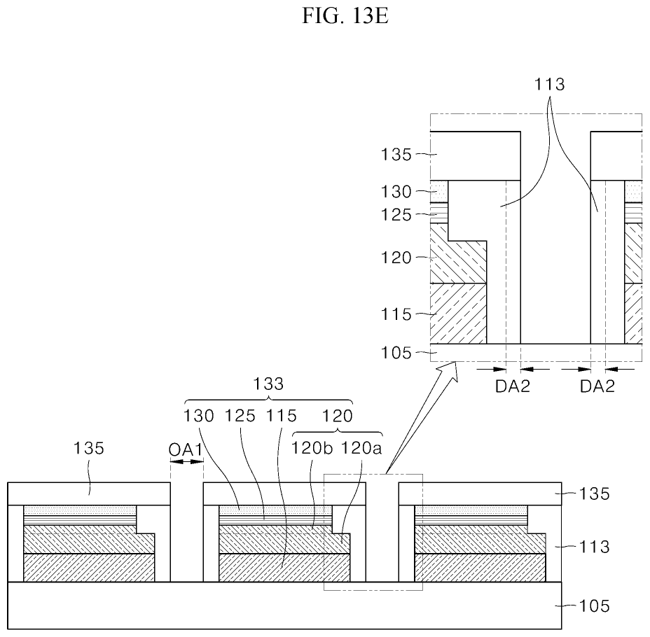

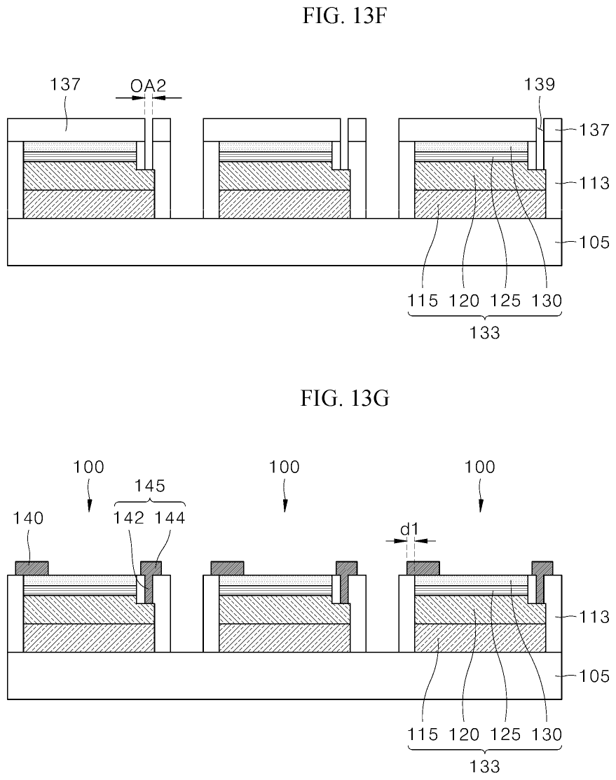

FIG. 13A to FIG. 13H are cross-sectional views illustrating a method for manufacturing the light-emitting element (e.g., 100 in FIG. 5B) according to the second embodiment of the present disclosure. In this regard, FIG. 13A is a cross-sectional view of FIG. 12 cut along a line III-III′.

Referring to FIG. 12 and FIG. 13A, the body portion 110 of the passivation pattern is formed on the growth substrate 105. The body portions 110 of the passivation pattern positioned adjacent to each other can be spaced apart from each other by a first space S1. As shown in FIG. 12, the body portions 110 of the passivation pattern can be arranged in the grid manner in a plan view.

The growth substrate 105 can include a material such as sapphire, silicon (Si), silicon carbide (SiC), or gallium arsenide (GaAs). However, the present disclosure is not limited thereto. The body portion 110 of the passivation pattern disposed on the growth substrate 105 can prevent the nitride-based semiconductor from growing thereon, and, to this end, can be made of an insulating material.

Referring to FIG. 13B, an epitaxy process is performed on the growth substrate 105 on which the body portions 110 of the passivation pattern have been formed. The epitaxy process can refer to a process of growing a material in a specific orientation on a surface of a crystalline material. In order to form a light-emitting element structure of a micro-LED, a GaN-based compound semiconductor should be grown on the growth substrate. At this time, each layer is grown according to crystallinity of an underlying layer.

When the epitaxy process is performed, the undoped semiconductor layer 115 and the lower portion 120a of the first semiconductor layer can be formed in a first space S1 between the adjacent body portions 110 of the passivation pattern. In this regard, as the body portion 110 of the passivation pattern includes the insulating material on which a semiconductor layer does not grow in the process of performing the epitaxy process, the GaN-based compound semiconductor layer can be selectively grown only on a remaining area except for the body portion 110 of the passivation pattern.

In this regard, the undoped semiconductor layer 115 can include an undoped nitride semiconductor. For example, the nitride semiconductor can be made of a GaN-based semiconductor material. The lower portion 120a of the first semiconductor layer can be formed on top of the undoped semiconductor layer 115 and can include a nitride semiconductor containing the first conductivity-type impurities. For example, the first conductivity-type impurities can include N-type impurities. The nitride semiconductor can be made of a GaN-based semiconductor material including GaN, AlGaN, InGaN, or AlInGaN. The N-type impurities used for doping of the lower portion 120a of the first semiconductor layer can include silicon (Si), germanium (Ge), selenium (Se), tellurium (Te), or carbon (C).

In one example, the lower portion 120a of the first semiconductor layer can be grown until the upper surface thereof is coplanar with the upper surface of the body portion 110 of the passivation pattern. Accordingly, adjacent stack structures of the undoped semiconductor layer 115 and the lower portion 120a of the first semiconductor layer can be spaced from each other via the body portion 110 of the passivation pattern.

Referring to FIG. 13C, a passivation layer is additionally deposited on the growth substrate 105, and a patterning process is performed thereon to form an extension 111 of the passivation pattern. Specifically, an insulating material layer as the passivation layer is deposited on the body portion 110 of the passivation pattern and lower portion 120a of the first semiconductor layer. Next, a patterning process is performed on the passivation layer to form the extension 111 extending from the body portion 110 and partially overlapping the surface of the lower portion 120a of the first semiconductor layer. Accordingly, the passivation pattern 113 can include the body portion 110 and the extension 111. The upper surface of the extension 111 of the passivation pattern 113 is positioned at a position higher than that of the upper surface of the lower portion 120a of the first semiconductor layer.

Adjacent extensions 111 of the passivation pattern 113 can be spaced apart from each other via a second space S2. In this regard, the second space S2 can have a relatively smaller width than that of the first space S1 in FIG. 13A. In the following drawings, the passivation pattern 113 including the body portion 110 and the extension 111 will be shown as a single structure.

Referring to FIG. 13D, the nitride semiconductor structure 133 is formed by sequentially forming the upper portion 120b of the first semiconductor layer, the active layer 125, and the second semiconductor layer 130 on an upper surface of the lower portion 120a of the first semiconductor layer exposed through the second space S2.

The upper portion 120b of the first semiconductor layer can grow from the exposed upper surface of the lower portion 120a of the first semiconductor layer. The upper portion 120b of the first semiconductor layer has a relatively smaller width than that of the lower portion 120a of the first semiconductor layer because a portion of the extension 111 of the passivation pattern 113 (see FIG. 13C) overlaps the lower portion 120a of the first semiconductor layer. Accordingly, the nitride semiconductor structure 133 can be formed to have a mesa structure in which the first semiconductor layer 120 has a step (e.g., at least at one side). In the embodiment of the present disclosure, as the nitride semiconductor structure 133 is formed to have a mesa structure during the growth process, an additional etching process for obtaining the mesa shape can be omitted. In the following drawings, the first semiconductor layer 120 including the lower portion 120a and the upper portion 120b will be shown as a single structure.

The upper surface of the second semiconductor layer 130 can be positioned at the same vertical level as that of the upper surface of the passivation pattern 113. Accordingly, the nitride semiconductor structure 133 can have an isolated shape due to the passivation pattern 113.

The active layer 125 is a layer for emitting light based on a combination of electrons and holes, and can have a multi-quantum well (MQW) structure having a well layer and a barrier layer having a higher band gap than that of the well layer. For example, the active layer 125 can be composed of an InGaN layer as the well layer and an AlGaN layer as the barrier layer.

The first semiconductor layer 120 can provide electrons to the active layer 125 and include a nitride semiconductor containing the N-type impurities as the first conductivity-type impurities. The nitride semiconductor can be made of a GaN-based semiconductor material including GaN, AlGaN, InGaN, or AlInGaN. The N-type impurities can include silicon (Si), germanium (Ge), tellurium (Te), selenium (Se) or carbon (C).

The second semiconductor layer 130 is formed on the active layer 125. The second semiconductor layer 130 provides holes to the active layer 125. The second semiconductor layer 130 can be made of the nitride semiconductor containing the second conductivity-type impurities. For example, the second conductivity-type impurities can include P-type impurities. The nitride semiconductor can be made of a GaN-based semiconductor material including GaN, AlGaN, InGaN, or AlInGaN. The P-type impurities contained in the second semiconductor layer 130 can include manganese (Mg), zinc (Zn), or beryllium (Be). In one example, in the present disclosure, an example in which the first semiconductor layer 120 and the second semiconductor layer 130 are made of the nitride semiconductor containing the N-type impurities and the nitride semiconductor including the P-type impurities, respectively is described. However, the present disclosure is not limited thereto. In another example, the first semiconductor layer 120 and the second semiconductor layer 130 can be made of a nitride semiconductor containing the P-type impurities and a nitride semiconductor containing the N-type impurities, respectively.

Referring to FIG. 13E, an etching process using a first mask pattern 135 is performed to space adjacent nitride semiconductor structures 133 from each other. To this end, a mask layer is formed on the passivation pattern 113 and an exposed surface of the second semiconductor layer 130, and then a photo process including an exposure and development process is performed thereon to form the first mask pattern 135 having an opening OA1 defined therein exposing a portion of the upper surface of the passivation pattern 113. The mask layer can include a photoresist material.

Subsequently, the etching process is performed using the first mask pattern 135 as an etch mask until the surface of the growth substrate 105 is exposed, thereby spacing adjacent nitride semiconductor structures 133 from each other. In this case, the etching process can be performed in a dry etching scheme. In one example, the dry etching scheme can be carried out using an inductively coupled plasma-reactive ion etch (ICP-RIE) using reactive gas.

In this regard, the entirety of the outer side surface of the nitride semiconductor structure 133 can be surrounded with the passivation pattern 113. The first opening OA1 of the first mask pattern 135 exposes the portion of the upper surface of the passivation pattern 113 overlapping a portion of the surface of the growth substrate 105. Accordingly, a damage by plasma may occur only on the side surface of the passivation pattern 113 during the dry etching, which is indicated by damaged areas DA2.

In other words, since the entirety of the outer side surface of the nitride semiconductor structure 133 including the undoped semiconductor layer 115, the first semiconductor layer 120, the active layer 125, and the second semiconductor layer 130 is covered completely with the passivation pattern 113, no damage due to the plasma occurs on the outer side surface of the nitride semiconductor structure 133 and the entire outer side surface of the nitride semiconductor structure 133 is well protected. This can prevent or minimize the occurrence of abnormal combinations of electrons and holes that do not participate in light emission due to the plasma-induced damage, and thus, can prevent or minimize decrease in light-emitting efficiency due to decrease in the light-emitting area.

Then, the first mask pattern 135 is removed.

Referring to FIG. 13F, an etching process using a second mask pattern 137 is performed to form a contact hole 139 exposing a portion of a surface of the first semiconductor layer 120. To this end, a mask layer is formed on the growth substrate 105, and a photo process including an exposure and development process is performed thereon to form the second mask pattern 137 having a second opening OA2 defined therein. The second opening OA2 of the second mask pattern 137 exposes a portion of an upper surface of the passivation pattern 113 corresponding to or overlapping a portion of a surface of the first semiconductor layer 120 having the mesa structure having the step. The mask layer can include a photoresist material.

Subsequently, the exposed portion of the passivation pattern 113 is etched using the second mask pattern 137 as an etch mask until the surface of the first semiconductor layer 120 is exposed, thereby forming the contact hole 139. The contact hole 139 can extend through the passivation pattern 113 to expose the first semiconductor layer 120.

Then, the second mask pattern 137 is removed.

Referring to FIG. 13G, an electrode material layer is formed on the nitride semiconductor structure 133 and the passivation pattern 113 and is patterned to form the first electrode 145 and the second electrode 140. In this way, the light-emitting element 100 is manufactured, which can be the same as the light-emitting element 100 of FIG. 5B of the second embodiment.

The first electrode 145 can include the column portion 142 connected to the exposed surface of the first semiconductor layer 120 and the head portion 144 extending from the column portion 142 and disposed on the upper surface of the passivation pattern 113. The column portion 142 of the first electrode 145 can be formed to entirely fill the contact hole 139. In this regard, as the column portion 142 of the first electrode 145 is formed in the contact hole 139, an outer side surface of the column portion 142 is surrounded with the passivation pattern 113.

The second electrode 140 can be disposed in an overlapping manner with at least a portion of the passivation pattern 113. Specifically, at least a portion of a surface of the second electrode 140 can overlap the upper surface of the passivation pattern 113 by a first width dl. Accordingly, the light-emitting area of the light-emitting element 100 can increase by a size of an area where the second electrode 140 overlaps the passivation pattern 113.

Further, the upper surface of the passivation pattern 113 can be coplanar with the upper surface of the second semiconductor layer 130 of the light-emitting element 100 while the passivation pattern 113 surrounds the outer side surface of the column portion 142 of the first electrode 145. Furthermore, each of the first electrode 145 and the second electrode 140 overlaps and is disposed on the upper surface of the passivation pattern 113. Accordingly, whereas a portion of a surface of an edge of each of the first electrode 31 and the second electrode 33 is covered by and is disposed under the passivation pattern 35, as shown in FIG. 1D, each of the first electrode 145 and the second electrode 140 has the exposed upper surface and the exposed side surface as shown in FIG. 13G where the first and second electrodes 145 and 140 are disposed over the passivation pattern 113.

Therefore, when the first electrode 145 and the second electrode 140 are respectively connected to electrodes of a display panel (or a display device, or other electronic device) in order to transfer the light-emitting element 100 to the display panel and electrically connect the light-emitting element 100 to the display panel, a contact area between and for the electrodes can be increased and thus contact resistance can be reduced.

As such, this light-emitting element 100 can have a lateral-type structure having the mesa structure.

The first electrode 145 and/or the second electrode 140 can be composed of a single layer or multiple layers made of a conductive material such as titanium (Ti), chromium (Cr), aluminum (Al) or gold (Au).

Referring to FIG. 13H, the growth substrate 105 is removed from the nitride semiconductor structures to obtain individual light-emitting elements 100a, 100b, and 100c separated from each other. In this case, the growth substrate 105 can be removed therefrom in a laser lift off (LLO) manner. The individual light-emitting elements 100a, 100b, and 100c obtained in this way can be then transferred to a package substrate. One light-emitting element constitutes one sub-pixel.

In the method for manufacturing the light-emitting element according to the first or second embodiment of the present disclosure, the passivation pattern is pre-formed on the growth substrate, and then the epitaxy process is performed to form the nitride semiconductor structure including the mesa structure. Thus, an additional dry etching process for forming the mesa structure can be omitted. This can fundamentally prevent plasma-induced damage that can otherwise occur on the nitride semiconductor structure in the dry etching process. As a result, since the abnormal combinations of electrons and holes that do not participate in light emission due to plasma-induced damage can be blocked or minimized, the light-emitting element having a target light-emitting area can be realized.

Further, as each of the first electrode and the second electrode 140 and 145 overlaps at least a portion of the passivation pattern 113, the light-emitting efficiency of the light-emitting element can be increased.

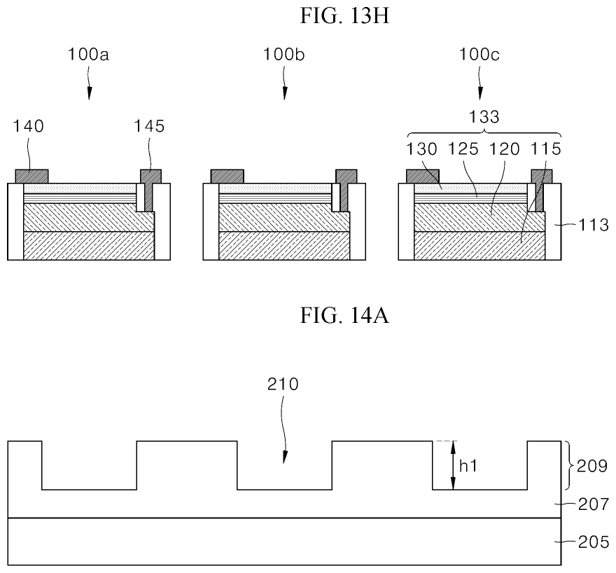

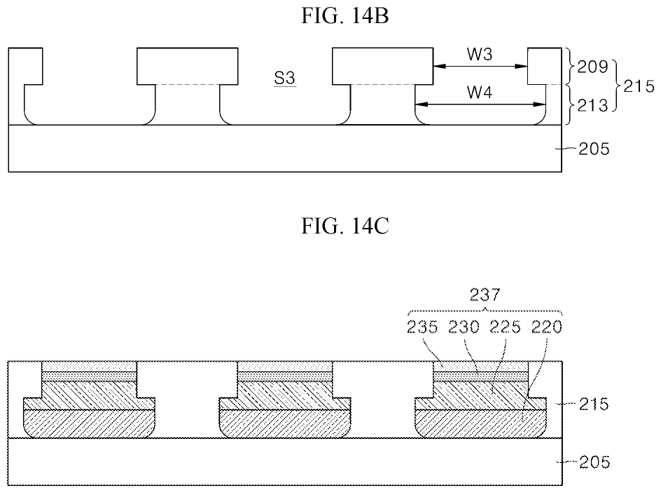

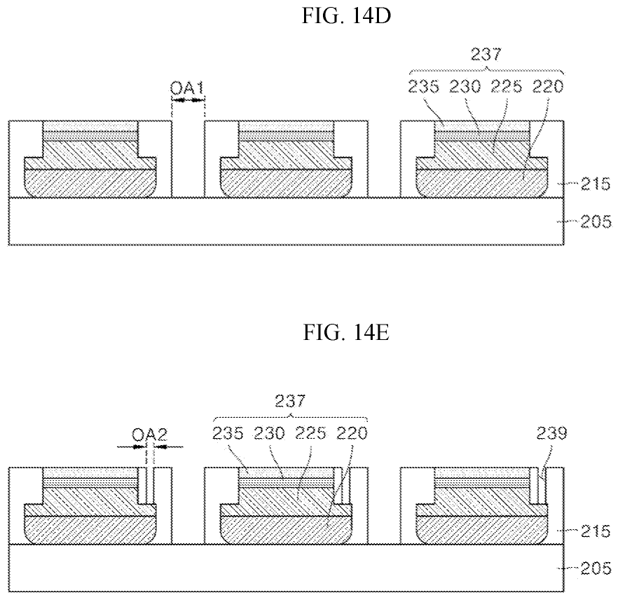

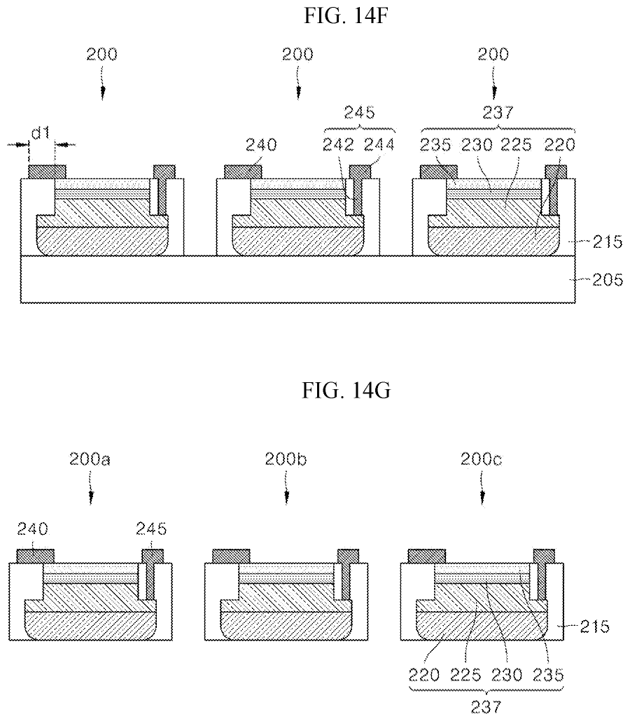

FIG. 14A to FIG. 14G are cross-sectional views illustrating a method for manufacturing the light-emitting element (e.g., 200 in FIG. 6) according to the third embodiment of the present disclosure.

Referring to FIG. 14A, a passivation layer 207 is formed on a growth substrate 205. Subsequently, a first etching process of etching an upper surface of the passivation layer 207 is performed to form the head portion 209 of the passivation pattern. The head portion 209 of the passivation pattern can be defined by a trench 210 having a first depth h1 from the upper surface of the passivation layer 207. The trench 210 can have a sidewall surface and a bottom surface that define the head portion 209 of the passivation pattern.

The first etching process can be performed in a dry etching scheme, and can be performed, for example, using plasma generated by activating a reactive gas. Such dry etching can have anisotropic etching characteristics. In this regard, a processing condition of the dry etching scheme can be controlled such that the head portion 209 of the passivation pattern has a flat sidewall surface. The passivation layer 207 can include a non-conductive material which can prevent the GaN-based compound semiconductor layer from growing from and on the passivation layer 207 in an epitaxy process to be performed later. In one example, the passivation layer 207 can include an insulating material.

Referring to FIG. 14B, a second etching process is performed on the passivation layer 207 having the head portion 209 of the passivation pattern to form the column portion 213 of the passivation pattern. The second etching process of patterning the passivation layer 207 is formed such that the passivation pattern 215 including the column portion 213 and the head portion 209 is formed on the growth substrate 205.

The second etching process can be performed in a wet etching scheme different from the dry etching scheme of the first etching process. As the second etching process is performed in a wet etching scheme having an isotropic etching characteristic, the head portion 209 of the passivation pattern 215 can have an undercut shape having a curvature such that the column portion 213 of the passivation pattern 215 can be formed so as to have the curvature. The undercut can refer to a phenomenon in which a lower portion of the head portion 209 of the passivation pattern 215 is partially removed horizontally and inwardly of the head portion. In other words, a lower portion of the head portion 209 of the passivation pattern 215 is additionally removed outwardly of the trench 210 (refer to FIG. 14A) such that an inner sidewall surface of the head portion 209 of the passivation pattern 215 and an inner sidewall surface of the column portion 213 of the passivation pattern 215 are not vertically aligned with each other in a line. The second etching process can be performed until the surface of the growth substrate 205 is exposed.

Accordingly, an inner space S3 in which the nitride semiconductor structure is to be formed can be defined between adjacent passivation patterns 215. The inner space S3 formed between the adjacent passivation patterns 215 can have an upper space defined between the head portions 209 of the adjacent passivation patterns 215 and a lower space defined between the column portions 213 of the adjacent passivation patterns 215. In this regard, a first width W3 of the upper space of the inner space S3 can be smaller than a second width W4 of the lower space thereof. Further, the upper space of the inner space S3 defined between the head portions 209 of the adjacent passivation patterns 215 can have a flat sidewall surface, while the lower space thereof defined between the column portions 213 of the adjacent passivation patterns 215 can have a curved sidewall surface or a flat sidewall surface (e.g., FIG. 6).

Referring to FIG. 14C, an epitaxy process is performed on the growth substrate 205 on which the passivation pattern 215 has been formed, thereby forming the nitride semiconductor structure 237.

When the epitaxy process is performed, the undoped semiconductor layer 220, the first semiconductor layer 225, the active layer 230, and the second semiconductor layer 235 are sequentially formed in the inner space S3 defined between the adjacent passivation patterns 215. The undoped semiconductor layer 220 can include an undoped nitride semiconductor. For example, the nitride semiconductor can be made of a GaN-based semiconductor material.

The first semiconductor layer 225 is formed on top of the undoped semiconductor layer 220 and provides electrons to the active layer 230. The first semiconductor layer 225 can include a nitride semiconductor containing the first conductivity-type impurities. For example, the first conductivity-type impurities can include N-type impurities. The nitride semiconductor can be made of a GaN-based semiconductor material including GaN, AlGaN, InGaN, or AlInGaN. The N-type impurities as the first conductivity-type impurities can include silicon (Si), germanium (Ge), selenium (Se), tellurium (Te), or carbon (C).

The active layer 230 is a layer for emitting light based on combination of electrons and holes, and can include a multi-quantum well (MQW) structure having a well layer and a barrier layer having a higher band gap than that of the well layer.

The second semiconductor layer 235 is formed on the active layer 230 and provides holes to the active layer 230. The second semiconductor layer 235 can be made of a nitride semiconductor containing P-type impurities as the second conductivity-type impurities. The nitride semiconductor can be made of a GaN-based semiconductor material including GaN, AlGaN, InGaN, or AlInGaN. The P-type impurities contained in the second semiconductor layer 235 can include manganese (Mg), zinc (Zn), or beryllium (Be). In one example, in the present disclosure, an example in which the first semiconductor layer 225 and the second semiconductor layer 235 are made of the nitride semiconductor containing the N-type impurities and the nitride semiconductor including the P-type impurities, respectively is described. However, the present disclosure is not limited thereto. In another example, the first semiconductor layer 225 and the second semiconductor layer 235 can be made of a nitride semiconductor containing the P-type impurities and a nitride semiconductor containing the N-type impurities, respectively.

An upper surface of the second semiconductor layer 235 disposed at a top level of the nitride semiconductor structure 237 can be coplanar with the upper surface of the passivation pattern 215. The passivation pattern 215 can have a shape surrounding the entirety of the outer side surface of the nitride semiconductor structure 237 except for the upper surface thereof.

As the first semiconductor layer 225 of the nitride semiconductor structure 237 occupies a portion of the upper space and a portion of the lower space in the inner space S3 formed between the passivation patterns 215 (see FIG. 14B), the first semiconductor layer 225 can be formed to have a step at each of both opposing side surfaces thereof. Accordingly, the nitride semiconductor structure 237 can have an inverted T shape in a cross-sectional view.

Referring to FIG. 14D, a patterning process is performed on the nitride semiconductor structure 237 surrounded with the passivation pattern 215 to spacing adjacent nitride semiconductor structures 237 from each other. To this end, a mask layer is formed on the passivation pattern 215 and an exposed surface of the second semiconductor layer 235, and a photo process including an exposure and development process is performed thereon to form a mask pattern having a first opening OA1 exposing a portion of an upper surface of the passivation pattern 215.

Subsequently, an etching process is performed on the portion of the passivation pattern 215 exposed through the first opening OA1 of the mask pattern until the surface of the growth substrate 205 is exposed, thereby spacing adjacent nitride semiconductor structures 237 from each other. In this regard, the etching process can be performed in a dry etching scheme using an inductively coupled plasma-reactive ion etch (ICP-RIE) using reactive gas.

In one example, the entirety of the outer side surface of the nitride semiconductor structure 237 is surrounded with the passivation pattern 215. Further, during the dry etching, the upper surface of the second semiconductor layer 235 is covered with the first mask pattern. Accordingly, damage that may be caused by plasma during the dry etching may occur only on the passivation pattern 215, but may not occur on the nitride semiconductor structure 237 including the second semiconductor layer 235, the active layer 230, the first semiconductor layer 225, and the undoped semiconductor layer 220. This can prevent the occurrence of the abnormal combinations of electrons and holes that do not participate in light emission due to the plasma-induced damage to the nitride semiconductor structure, thereby preventing the decrease in light-emitting efficiency.

Referring to FIG. 14E, an etching process for forming the contact hole 239 exposing a portion of a surface of the first semiconductor layer 225 is performed. To this end, a mask pattern having an opening defined therein exposing a portion of the upper surface of the passivation pattern 215 corresponding to or overlapping a portion of an upper surface of a stepped portion of the first semiconductor layer 225 is formed on the growth substrate 205. Subsequently, an etching process is performed thereon using the mask pattern as an etching mask to form the contact hole 239 extending through the passivation pattern 215 in an area corresponding to or overlapping the portion of the upper surface of the stepped portion of the first semiconductor layer 225 so as to expose the portion of the upper surface of the stepped portion of the first semiconductor layer 225. Then, the mask pattern is removed.

Referring to FIG. 14F, an electrode material layer is formed on the nitride semiconductor structure 237 and the passivation pattern 215 and is patterned to form the first electrode 245 and the second electrode 240. Thus, the light-emitting element 200 is manufactured.

The first electrode 245 can include the column portion 242 contacting the portion of the upper surface of the stepped portion of the first semiconductor layer 225, and the head portion 244 extending from the column portion 242 and disposed on the upper surface of the passivation pattern 215. The second electrode 240 can be disposed on the second semiconductor layer 235 so that at least a portion by a width dl of the passivation pattern 215 overlaps with the upper surface of the passivation pattern 215. Accordingly, the light-emitting area of the light-emitting element 200 can increase by a size of the increased area (e.g., dl increased) where the second electrode 240 overlaps the passivation pattern 215.

The first electrode 245 and/or the second electrode 240 can be embodied as a single layer or multiple layers made of a conductive material such as titanium (Ti), chromium (Cr), aluminum (Al), or gold (Au).

In addition, the growth substrate 205 can be removed from the light-emitting elements 200 to obtain individual light-emitting elements 200a, 200b, and 200c separated from each other. Each of the light-emitting elements can have a lateral-type structure having a mesa structure.

In another example, the manufacturing method according to the embodiment of the present disclosure can also be applied to the vertical-type structure to easily form a plurality of light-emitting elements. This will be described with reference to the drawings below.

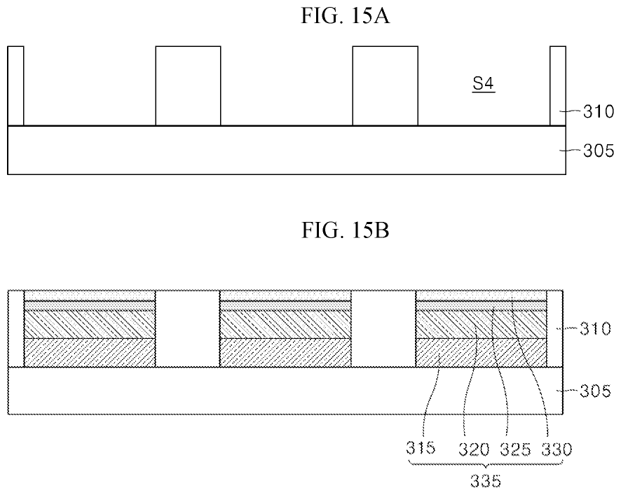

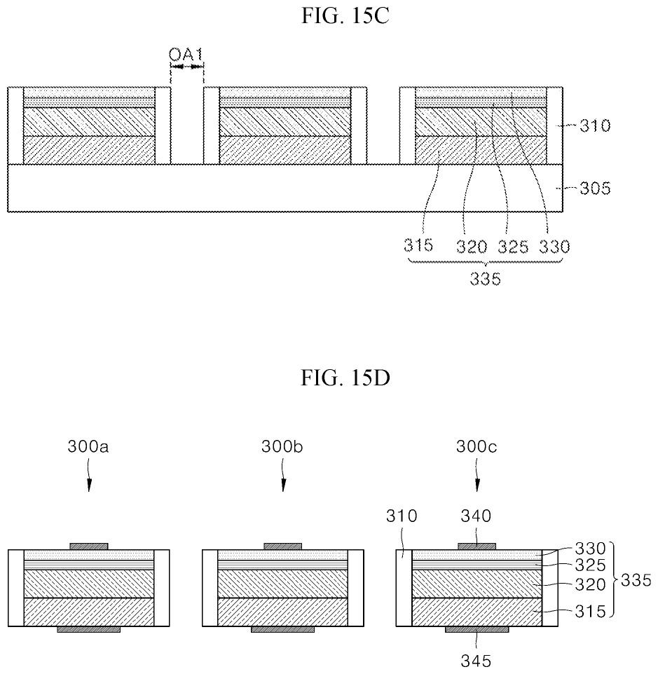

FIG. 15A to FIG. 15D are cross-sectional views illustrating a method for manufacturing the light-emitting element (e.g., 300 in FIG. 7) according to the fourth embodiment of the present disclosure.

Referring to FIG. 15A, the passivation pattern 310 is formed on the growth substrate 305. As the method of forming the passivation pattern 310 is the same as that in FIG. 12, a description thereof will be omitted.

Adjacent passivation patterns 310 can be spaced apart from each other so that a first space S4 is defined therebetween. As shown in FIG. 12, the passivation patterns 310 can be arranged in a grid manner in a plan view thereof.

The growth substrate 305 can include a material such as sapphire, silicon (Si), silicon carbide (SiC) or gallium arsenide (GaAs). However, the present disclosure is not limited thereto. The passivation pattern 310 formed on the growth substrate 305 plays a role of pre-specifying a position at which the nitride-based semiconductor grows thereafter. For example, the nitride-based semiconductor grows only at a position where the growth substrate 305 is exposed, except for a position where the passivation pattern 310 is formed. The passivation pattern 310 can be made of a material on which the nitride-based semiconductor cannot grow, for example, an insulating material.

The passivation pattern 310 can be formed to have the same height as that of the nitride semiconductor structure to be formed later.

Referring to FIG. 15B, an epitaxy process is performed on the growth substrate 305 on which the passivation pattern 310 has been formed to form the nitride semiconductor structure 335.

When the epitaxy process is performed, the undoped semiconductor layer 315, the first semiconductor layer 320, the active layer 325, and the second semiconductor layer 330 are sequentially formed on the growth substrate 305 and in the first space S4 defined between adjacent passivation patterns 310 to form the nitride semiconductor structure 335. As the passivation pattern 310 is made of the insulating material, the nitride-based semiconductor does not grow on the exposed surface of the passivation pattern 310.

The upper surface of the second semiconductor layer 330 disposed at a top level of the nitride semiconductor structure 335 can be coplanar with the upper surface of the passivation pattern 310. Accordingly, the nitride semiconductor structure 335 can have an isolated shape due to the passivation pattern 310.

The undoped semiconductor layer 315 can include an undoped nitride semiconductor. For example, the nitride semiconductor can be made of a GaN-based semiconductor material.

The first semiconductor layer 320 is formed on top of the undoped semiconductor layer 315 and provides electrons to the active layer 325. The first semiconductor layer 320 can include a nitride semiconductor containing the first conductivity-type impurities. For example, the first conductivity-type impurities can include N-type impurities. The nitride semiconductor can be made of a GaN-based semiconductor material including GaN, AlGaN, InGaN, or AlInGaN. The N-type impurities as the first conductivity-type impurities can include silicon (Si), germanium (Ge), selenium (Se), tellurium (Te), or carbon (C).

The active layer 325 can be a layer for emitting light based on combination of electrons and holes, and can have a multi-quantum well (MQW) structure having a well layer and a barrier layer having a higher band gap than that of the well layer.

The second semiconductor layer 330 is formed on the active layer 325 and provides holes to the active layer 325. The second semiconductor layer 330 can be made of a nitride semiconductor containing the P-type impurities as the second conductivity-type impurities. The nitride semiconductor can be made of a GaN-based semiconductor material including GaN, AlGaN, InGaN, or AlInGaN. The P-type impurities contained in the second semiconductor layer 330 can include manganese (Mg), zinc (Zn), or beryllium (Be). In one example, in the present disclosure, an example in which the first semiconductor layer 320 and the second semiconductor layer 330 are made of the nitride semiconductor containing the N-type impurities and the nitride semiconductor including the P-type impurities, respectively is described. However, the present disclosure is not limited thereto. In another example, the first semiconductor layer 320 and the second semiconductor layer 330 can be made of a nitride semiconductor containing the P-type impurities and a nitride semiconductor containing the N-type impurities, respectively.

An inner sidewall of the passivation pattern 310 can have a flat surface. Accordingly, both side ends of the undoped semiconductor layer 315, the first semiconductor layer 320, the active layer 325, and the second semiconductor layer 330 of the nitride semiconductor structure 335 can be respectively aligned with each other in a line.

Referring to FIG. 15C, a patterning process is performed on the nitride semiconductor structure 335 surrounded with the passivation pattern 310 to spaced adjacent nitride semiconductor structures 335 from each other. In the patterning process, first, a mask pattern having an opening exposing defined therein a portion of an upper surface of the passivation pattern 310 disposed between adjacent nitride semiconductor structures 335 is formed. Then, an etching process can be performed using this mask pattern such that the portion of the passivation pattern 310 exposed through the opening is etched away until the surface of the growth substrate 305 is exposed. In this regard, the etching process can be performed in a dry etching scheme using an inductively coupled plasma-reactive ion etch (ICP-RIE) using reactive gas.

In one example, the entirety of the outer side surface of the nitride semiconductor structure 335 is surrounded with the passivation pattern 310. Further, during the dry etching process, the upper surface of the second semiconductor layer 330 is covered with the mask pattern. Accordingly, damage that can be caused by the plasma during the dry etching occurs only on the passivation pattern 310 exposed to the plasma. However, the plasma during the dry etching does not affect the nitride semiconductor structure 335 including the second semiconductor layer 330, the active layer 325, the first semiconductor layer 320, and the undoped semiconductor layer 315. This can prevent the occurrence of the abnormal combinations of electrons and holes that do not participate in light emission due to the plasma-induced damage to the nitride semiconductor structure, thereby preventing the decrease in light-emitting efficiency.

Referring to FIG. 15D, the growth substrate 305 is removed from the nitride semiconductor structures in a laser lift off manner. Thus, individual light-emitting elements 300a, 300b, and 300c separated from each other can be obtained, where each light-emitting element 300a, 300b, 300c can be the same as the light-emitting element 300 of FIG. 7.

Here, the first electrode 345 is formed on the surface of the undoped semiconductor layer 315 of the light-emitting element 300 and thus is electrically connected to the first semiconductor layer 320. The second electrode 340 is formed on the upper surface of the second semiconductor layer 330 and is electrically connected to the second semiconductor layer 330.

The first electrode 345 and/or the second electrode 340 can be embodied as a single layer or multiple layers made of a conductive material such as titanium (Ti), chromium (Cr), aluminum (Al), or gold (Au).

The light-emitting element according to the fourth embodiment of the present disclosure can have the vertical-type structure.

In one example, in a process of depositing the passivation layer prior to forming the passivation pattern, it can be difficult to deposit the passivation layer so thick enough to cover both opposing side surfaces of the first semiconductor layer, the active layer, and the second semiconductor layer. Accordingly, a separate scheme for depositing the passivation pattern with a thickness sufficient to cover both opposing side surfaces of the first semiconductor layer, the active layer, and the second semiconductor layer is required.

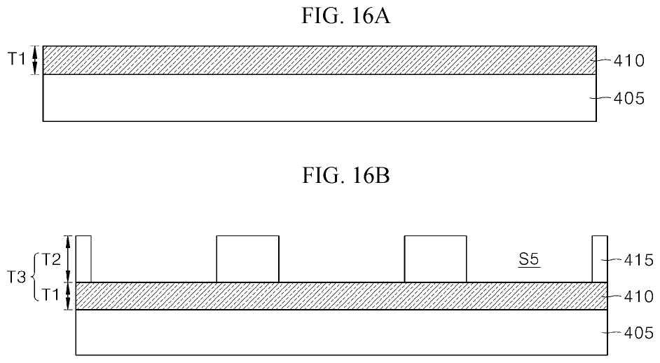

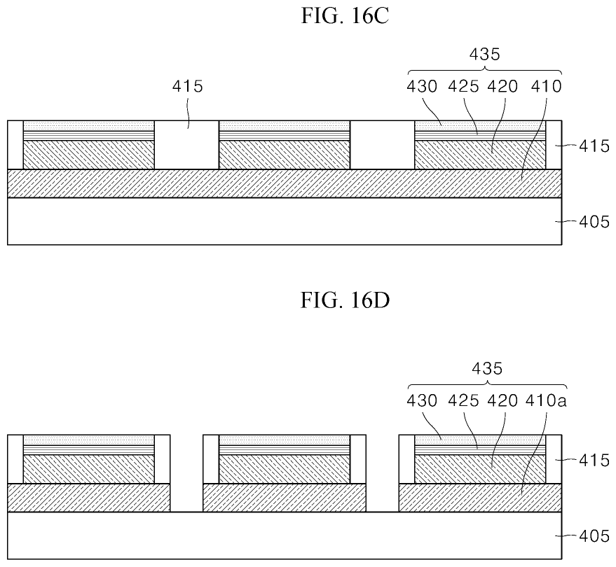

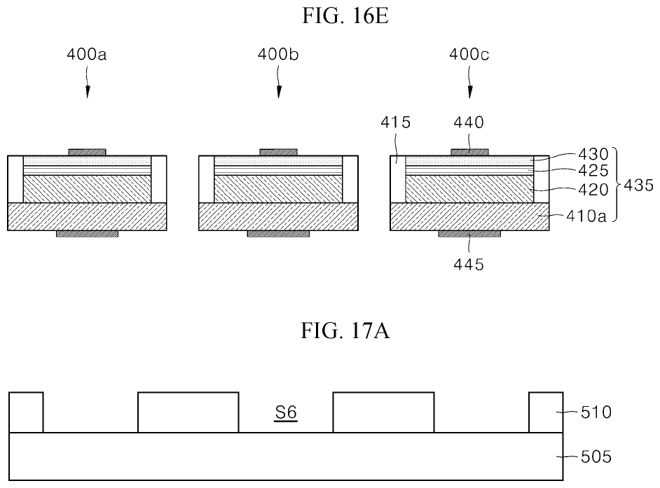

FIG. 16A to FIG. 16E are cross-sectional views illustrating a method for manufacturing the light-emitting element (e.g., 400 in FIG. 8) according to the fifth embodiment of the present disclosure.

Referring to FIG. 16A, the undoped semiconductor material layer 410 is grown on a growth substrate 405 so as to have a first height T1. The undoped semiconductor material layer 410 can include an undoped nitride semiconductor. For example, a nitride semiconductor can be made of a GaN-based semiconductor material.

Referring to FIG. 16B, a passivation pattern 415 is formed on the undoped semiconductor material layer 410. Specifically, a passivation layer is deposited on the undoped semiconductor material layer 410 and a patterning process is performed thereon to form the passivation pattern 415.

Adjacent passivation patterns 415 can be spaced apart from each other via a first space S5. The passivation pattern 415 can have a second height T2. As shown in FIG. 12, the passivation patterns 415 can be arranged in a grid manner in a top view thereof. According to the fifth embodiment of the present disclosure, the undoped semiconductor material layer 410 as a base is formed under the passivation pattern 415 so as to have the first height T1, and then the passivation pattern 415 is formed so as to have the second height T2, thereby easily securing a thickness T3 of the light-emitting element to be finally formed. Accordingly, the passivation pattern which it can be difficult to form so as to have the target thickness T3 of the light-emitting element can be formed so as to have a relatively smaller second height T2.

Referring to FIG. 16C, an epitaxy process is performed on an exposed portion of the undoped semiconductor material layer 410 disposed between adjacent passivation patterns 415 to form the nitride semiconductor structure 435. When the epitaxy process is performed, the first semiconductor layer 420, the active layer 425, and the second semiconductor layer 430 can be formed only on the exposed portion of the undoped semiconductor material layer 410 disposed between adjacent passivation patterns 415 and in the first space S5 defined therebetween.

The upper surface of the second semiconductor layer 430 disposed at a top level of the nitride semiconductor structure 435 can be coplanar with the upper surface of the passivation pattern 415. Accordingly, outer side surfaces of the first semiconductor layer 420, the active layer 425, and the second semiconductor layer 430 of the nitride semiconductor structure 435 can be surrounded with the passivation pattern 415.

The first semiconductor layer 420 can be formed on top of the undoped semiconductor material layer 410 and can include a nitride semiconductor containing the N-type impurities as the first conductivity-type impurities. The N-type impurities can include silicon (Si), germanium (Ge), tellurium (Te), selenium (Se) or carbon (C). The active layer 425 can have a multi-quantum well (MQW) structure including a well layer and a barrier layer having a higher band gap than that of the well layer. The second semiconductor layer 430 can be formed on the active layer 425 and can include a nitride semiconductor containing the second conductivity-type impurities. The P-type impurities contained in the second semiconductor layer 430 can include manganese (Mg), zinc (Zn), or beryllium (Be).

In one example, in the present disclosure, an example in which the first semiconductor layer 420 and the second semiconductor layer 430 are made of the nitride semiconductor containing the N-type impurities and the nitride semiconductor including the P-type impurities, respectively is described. However, the present disclosure is not limited thereto. In another example, the first semiconductor layer 420 and the second semiconductor layer 430 can be made of a nitride semiconductor containing the P-type impurities and a nitride semiconductor containing the N-type impurities, respectively.

Referring to FIG. 16D, a patterning process is performed on the nitride semiconductor structure 435 and the passivation pattern 415 to space adjacent nitride semiconductor structures 435 from each other. In the patterning process, first, a mask pattern having an opening defined therein exposing a portion of an upper surface of the passivation pattern 415 disposed between adjacent nitride semiconductor structures 435 is formed. Then, an etching process is performed using this mask pattern such that a portion of each of the passivation pattern 415 and the undoped semiconductor material layer 410 disposed under the passivation pattern 415 in an area overlapping the opening is etched away until the surface of the growth substrate 405 is exposed. In this regard, the etching process can be performed in a dry etching scheme using an inductively coupled plasma-reactive ion etch (ICP-RIE) using reactive gas.

In one example, the entirety of the outer side surface of the first semiconductor layer 420, the active layer 425, and the second semiconductor layer 430 constituting the light-emitting area of the nitride semiconductor structure 435 is surrounded with the passivation pattern 415. Further, during the dry etching process, the upper surface of the second semiconductor layer 430 is covered with the mask pattern. Accordingly, damage that can be caused by plasma during the dry etching process occurs in the passivation pattern 415 exposed to the plasma. However, the second semiconductor layer 430, the active layer 425, and the first semiconductor layer 420 constituting the light-emitting area may not be affected by the plasma during the dry etching process. This can prevent the occurrence of abnormal combinations of electrons and holes that do not participate in light emission due to the plasma-induced damage to the second semiconductor layer 430, the active layer 425, and the first semiconductor layer 420, thereby preventing the decrease in light-emitting efficiency.

Referring to FIG. 16E, the growth substrate 405 is removed from the nitride semiconductor structures to obtain individual light-emitting elements 400a, 400b, and 400c as separated from each other. Here, the first electrode 445 is formed on the surface of the undoped semiconductor layer 410a of the light-emitting element 400 and thus is electrically connected to the first semiconductor layer 420, while the second electrode 440 is formed on the upper surface of the second semiconductor layer 430 and is electrically connected thereto.

The first electrode 445 and/or the second electrode 440 can be embodied as a single layer or multiple layers made of a conductive material such as titanium (Ti), chromium (Cr), aluminum (Al) or gold (Au). This light-emitting element 400 can have the vertical-type structure, and can be the same as the light-emitting element 400 of FIG. 8.

The method for manufacturing the light-emitting element according to the fourth embodiment of the present disclosure pre-grows the undoped semiconductor material layer 410 so as to have the first height T1 and then forms the passivation pattern 415 so as to have the second height T2. Thus, a time needed to form the passivation patterns can then be reduced such that an overall process time can be reduced.

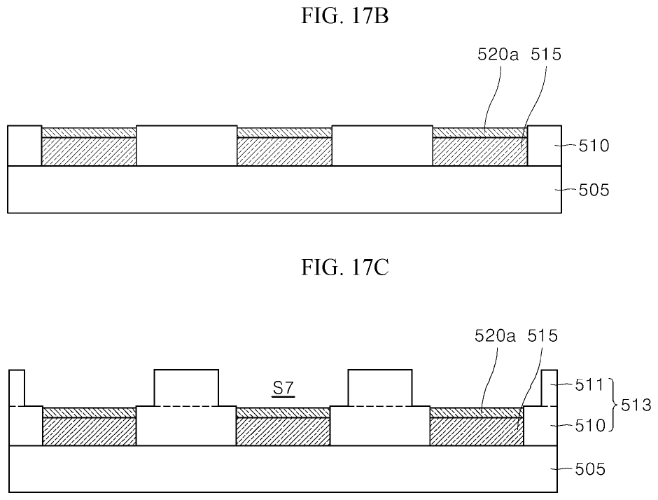

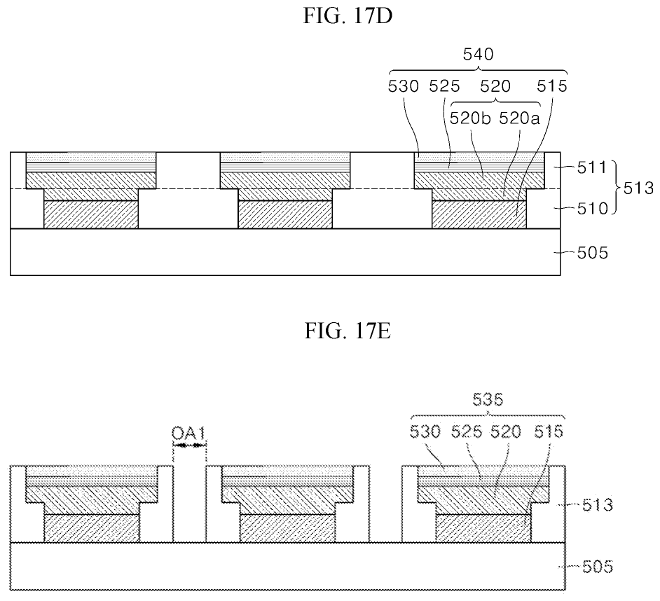

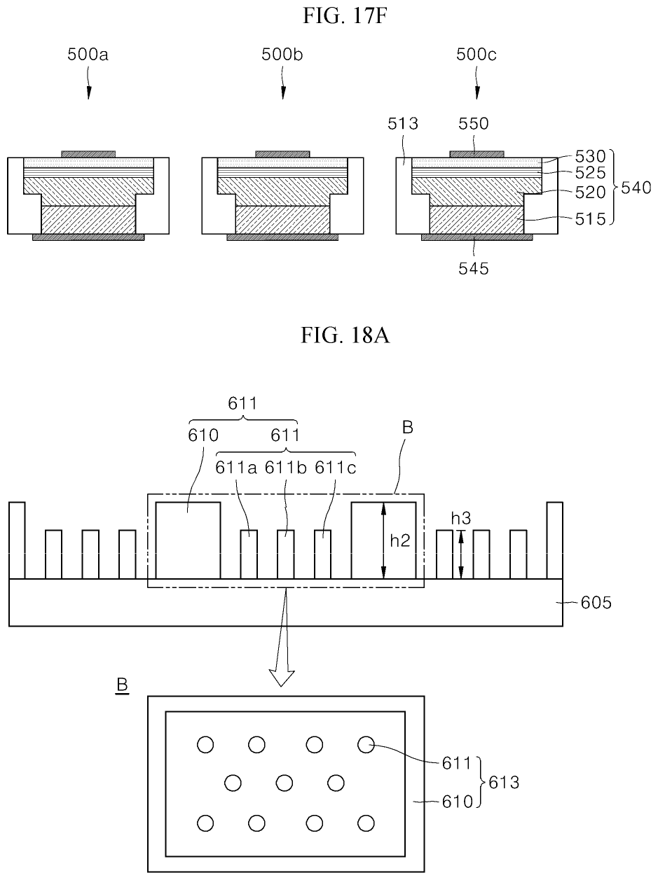

FIG. 17A to FIG. 17F are cross-sectional views illustrating a method for manufacturing the light-emitting element (e.g., 500 in FIG. 9B) according to the sixth embodiment of the present disclosure.

Referring to FIG. 17A, the body portion 510 of the passivation pattern is formed on the growth substrate 505. The body portions 510 of adjacent passivation patterns can be spaced apart from each other so that a first space S6 is defined therebetween. As shown in FIG. 12, the body portions 510 of the passivation patterns can be arranged in a grid manner in a plan view thereof.

The growth substrate 505 can include a material such as sapphire, silicon (Si), silicon carbide (SiC) or gallium arsenide (GaAs). However, the present disclosure is not limited thereto. The body portion 510 of the passivation pattern disposed on the growth substrate 505 serves to prevent the nitride-based semiconductor from growing therefrom thereafter, and, to this end, can be made of an insulating material.

Referring to FIG. 17B, an epitaxy process is performed on the growth substrate 505 on which the body portions 510 of the passivation patterns have been formed such that the undoped semiconductor layer 515 and the lower portion 520a of the first semiconductor layer are formed in the first space S6.

When the epitaxy process is performed, a semiconductor layer is grown on the exposed surface of the growth substrate 505 in the first space S6. In an embodiment of the present disclosure, the body portion 510 of the passivation pattern is formed on the growth substrate 505. Thus, the body portion 510 of the passivation pattern serves to prevent the growth of the nitride-based semiconductor thereon. Accordingly, in the epitaxy process, the semiconductor layer can grow only in the remaining area except for the area where the body portion 510 of the passivation pattern is located.

The lower portion 520a of the first semiconductor layer formed in the epitaxy process can be grown until the upper surface thereof is coplanar with the upper surface of the body portion 510 of the passivation pattern. Accordingly, adjacent stack structures, each composed of the undoped semiconductor layer 515 and the lower portion 520a of the first semiconductor layer, can be separated from each other via the body portion 510 of the passivation pattern.

In this regard, the undoped semiconductor layer 515 can include an undoped nitride semiconductor. For example, a nitride semiconductor can be made of a GaN-based semiconductor material. The lower portion 520a of the first semiconductor layer can be formed on top of the undoped semiconductor layer 515 and can include a nitride semiconductor containing the first conductivity-type impurities. For example, the first conductivity-type impurities can include N-type impurities. The nitride semiconductor can be made of a GaN-based semiconductor material including GaN, AlGaN, InGaN, or AlInGaN. The N-type impurities used for doping of the lower portion 520a of the first semiconductor layer can include silicon (Si), germanium (Ge), selenium (Se), tellurium (Te), or carbon (C).

Referring to FIG. 17C, a process of additionally depositing and patterning a passivation layer on the growth substrate 505 is performed to form the head portion 511 of a passivation pattern. Specifically, an insulating material layer as a passivation layer is deposited on the growth substrate 505 and the body portion 510 of the passivation pattern. Next, a patterning process is performed on the passivation layer to form the head portion 511 having a relatively smaller width than that of the body portion 510. The passivation pattern 513 can include the body portion 510 and the head portion 511 having the width smaller than that of the body portion 510.

An upper surface of the head portion 511 of the passivation pattern 513 is positioned at a higher level than that of an upper surface of the lower portion 520a of the first semiconductor layer. As the head portion 511 of the passivation pattern 513 is formed to have a relatively smaller width than that of the body portion 510 thereof, a second space S7 having a relatively larger width than that of the first space S6 (see FIG. 17A) defined between the body portions 510 of the adjacent passivation patterns 513 can be defined between the head portions 511 of the adjacent passivation patterns 513.

Here, the head portions 511 of the passivation patterns 513 can be arranged in a grid manner in a plan view thereof as shown in FIG. 12.

Referring to FIG. 17D, the nitride semiconductor structure 540 can be formed by sequentially stacking the upper portion 520b of the first semiconductor layer, the active layer 525, and the second semiconductor layer 530 on the lower portion 520a of the first semiconductor layer NS and an exposed surface of the body portion 510 of the passivation pattern 513 and in the second space S7.

The upper portion 520b of the first semiconductor layer can be grown from and on an exposed surface of the lower portion 520a of the first semiconductor layer. As the head portion 511 of the passivation pattern 513 has a smaller width than the body portion 510 thereof, the upper portion 520b of the first semiconductor layer fills a lower portion of the second space S7 which has a relatively larger width than that of the first space S6. Accordingly, the upper portion 520b of the first semiconductor layer can have a relatively larger width than that of the lower portion 520a of the first semiconductor layer.

Accordingly, the cross-sectional shape of the nitride semiconductor structure 540 can have a ‘T’ shape. In the following drawings, the first semiconductor layer 520 including the lower portion 520a and the upper portion 520b will be shown as a single structure.

The first semiconductor layer 520 can provide electrons to the active layer 525 and can include a nitride semiconductor containing the N-type impurities as the first conductivity-type impurities. The second semiconductor layer 530 can provide holes to the active layer 525 and can be made of the nitride semiconductor that contain s the P-type impurities as the second conductivity-type impurities. The nitride semiconductor can be made of a GaN-based semiconductor material including GaN, AlGaN, InGaN, or AlInGaN. The N-type impurities used for doping of the first semiconductor layer 520 can include silicon (Si), germanium (Ge), selenium (Se), tellurium (Te), or carbon (C). The P-type impurities contained in the second semiconductor layer 530 can include manganese (Mg), zinc (Zn), or beryllium (Be).

In one example, in the present disclosure, an example in which the first semiconductor layer 520 and the second semiconductor layer 530 are made of the nitride semiconductor containing the N-type impurities and the nitride semiconductor including the P-type impurities, respectively is described. However, the present disclosure is not limited thereto. In another example, the first semiconductor layer 520 and the second semiconductor layer 530 can be made of a nitride semiconductor containing the P-type impurities and a nitride semiconductor containing the N-type impurities, respectively.

The active layer 525 can have a multi-quantum well (MQW) structure including a well layer and a barrier layer having a higher band gap than that of the well layer. The active layer 525 can emit light based on combinations of electrons and holes respectively supplied from the first semiconductor layer 520 and the second semiconductor layer 530.

Referring to FIG. 17E, a patterning process for spacing and thus separating adjacent nitride semiconductor structures 540 from each other is performed. The patterning process can be performed based on an etching process using a mask pattern having an opening OA1 defined therein exposing a portion of the upper surface of the passivation pattern 513 between adjacent nitride semiconductor structures 540. The etching process can be performed to etch the portion of the passivation pattern 513 exposed through the opening OA1 of the mask pattern until the surface of the growth substrate 505 is exposed. Thus, the nitride semiconductor structures 540 can be separated and spaced from each. In one example, the etching process can be performed in a dry etching scheme using an inductively coupled plasma-reactive ion etch (ICP-RIE) using reactive gas.

The outer side surface of the nitride semiconductor structure 540 is entirely surrounded with the passivation pattern 513. Further, the upper surface of the nitride semiconductor structure 540 is covered with the mask pattern during the etching process. Accordingly, the plasma-induced damage occurs only on the side surface of the passivation pattern 513 during the dry etching process.

Accordingly, the occurrence of the abnormal combinations of electrons and holes that do not participate in light emission due to the plasma-induced damage to the nitride semiconductor structure can be suppressed, such that the light-emitting efficiency can be prevented from being lowered.

Further, the first space S6 disposed between the body portions 510 of the passivation patterns 513 has the relatively smaller width than that of the second space S7 disposed between the head portions 511 of the passivation patterns 513. Accordingly, in the process of performing the epitaxy process in the first space S6, the nitride semiconductor layer can occur in a state in which a contact area between the growth substrate 505 and the nitride semiconductor layer is relatively reduced. In other words, the nitride semiconductor layer can grow on the growth substrate 505 in a state in which the contact area between the growth substrate 505 and the nitride semiconductor layer does not correspond to a relatively larger width of the second space S7 but corresponds to a relatively smaller width of the first space S6.

The growth substrate 505 and the nitride semiconductor layer have different lattice constants. Thus, as a thickness by which the nitride semiconductor layer grows on the growth substrate 505 increases, wafer warping due to lattice mismatch can occur. This lattice mismatch increases as the contact area between the growth substrate 505 and the nitride semiconductor layer increases, more adversely affecting the quality of the nitride semiconductor layer.

In this regard, in accordance with the present disclosure, the nitride semiconductor layer can grow in a state where the contact area between the growth substrate 505 and the nitride semiconductor layer is reduced, thereby improving the quality of the nitride semiconductor layer and reducing the occurrence of the warping of the wafer.

In addition, as a width of a lower portion of the nitride semiconductor structure 540 is relatively smaller than a width of an upper portion thereof, current injection efficiency can be improved due to the current confinement phenomenon.

Specifically, the width of the lower portion of the nitride semiconductor structure 540 can be equal to the width of the upper portion thereof. In this case, when a first magnitude of current is applied thereto, the current flows from a large sized area to a large sized area, such that the light-emitting efficiency can decrease. In contrast thereto, in the present embodiment, the width of the lower portion of the nitride semiconductor structure 540 is relatively smaller than the width of the upper portion thereof. When the second electrode 550 is disposed on the second semiconductor layer 530 containing the P-type impurities of the nitride semiconductor structure 540, the relatively larger number of holes can be generated in a position adjacent to the second electrode 550 than the number of holes generated in an area where the second electrode 550 is not disposed. In this case, because the width of the lower portion of the nitride semiconductor structure 540 is relatively smaller than the width of the upper portion thereof, the current can flow densely in the lower portion of the nitride semiconductor structure 540. Thus, the current can flow to an area in which a relatively larger number of holes are generated, thereby promoting the combinations of electrons and holes for light emission. Thus, the light-emitting efficiency can be increased.

Referring to FIG. 17F, a process of removing the growth substrate 505 from the nitride semiconductor structures 540 in a laser lift-off manner is performed to obtain individual light-emitting elements 500a, 500b, and 500c which are spaced and separated from each other. Here, the first electrode 545 is formed on (e.g., under or below) a surface of the undoped semiconductor layer 515 of the light-emitting element 500, and thus is electrically connected to the first semiconductor layer 520. The second electrode 550 is formed on the upper surface of the second semiconductor layer 530 and is electrically connected thereto.

The first electrode 545 and/or the second electrode 550 can be composed of a single layer or multiple layers made of a material selected from the group consisting of titanium (Ti), chromium (Cr), aluminum (Al) and gold (Au).

The light-emitting element according to the fifth embodiment of the present disclosure can have the vertical-type structure, and each of the light-emitting element 500a, 500b, 550c can be the same as the light-emitting element 500 of FIG. 9B.

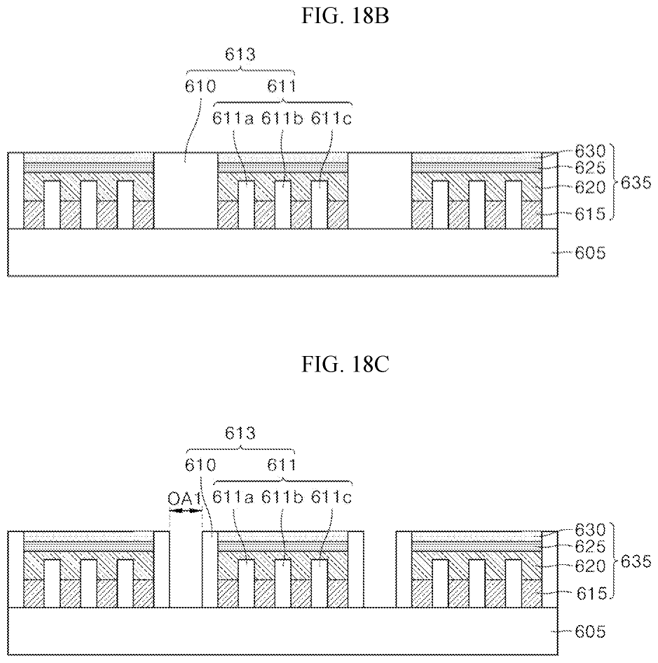

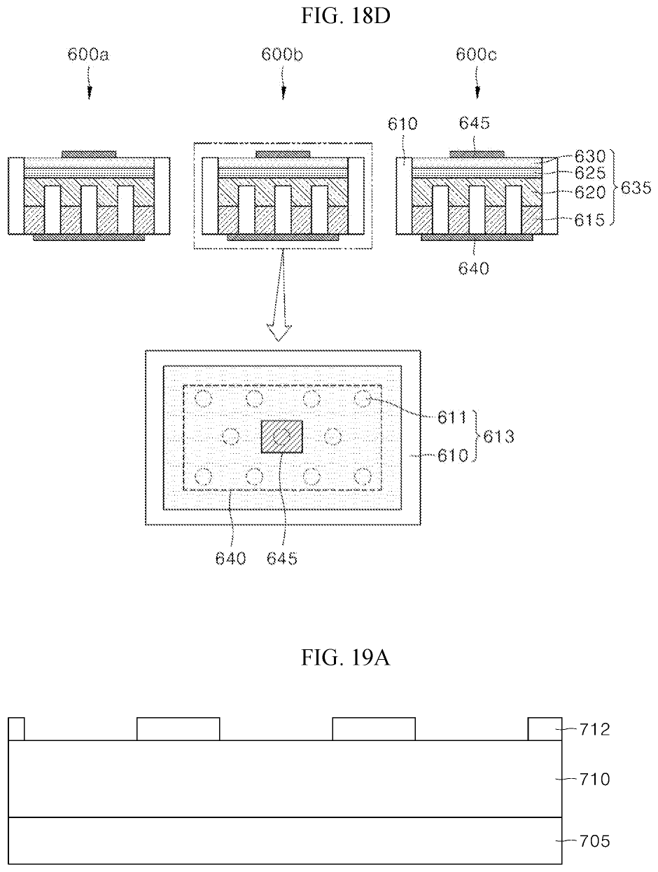

FIG. 18A to FIG. 18D are cross-sectional views illustrating a method for manufacturing the light-emitting element (e.g., 600 in FIG. 10A) according to the seventh embodiment of the present disclosure.

Referring to FIG. 18A, the passivation pattern 613 is formed on a growth substrate 605. The passivation pattern 613 can include the first pattern portion 610 and the second pattern portion 611.

The first pattern portion 610 of the passivation pattern 613 can be formed to have a first height h2, and the second pattern portion 611 can be formed to have a second height h3. As the first pattern portion 610 of the passivation pattern 613 is formed to have the same height as a final height of the nitride semiconductor structure to be formed later, the first height h2 can be relatively larger than the second height h3 of the second pattern portion 611.

Referring to a top view of a ‘B’ portion of the passivation pattern 613 formed on the growth substrate 605, the first pattern portion 610 of the passivation pattern 613 serves to specify a position of the nitride semiconductor structure to be formed later, and can be formed to have a rectangular ring shape having four sides. The first pattern portions 610 can be arranged in a lattice manner. The second pattern portion 611 of the passivation pattern 613 can be disposed inwardly of the first pattern portion 610 and can include a plurality of column portions 611a spaced apart from each other.

The growth substrate 605 can include a material such as sapphire, silicon (Si), silicon carbide (SiC) or gallium arsenide (GaAs). However, the present disclosure is not limited thereto. The passivation pattern 613 disposed on the growth substrate 605 and including the first pattern portion 610 and the second pattern portion 611 serves to prevent the nitride-based semiconductor from growing thereon thereafter, and, to this end, can be made of an insulating material.

Referring to FIG. 18B, an epitaxy process is performed on the growth substrate 605 and the passivation pattern 613 including the first pattern portion 610 and the second pattern portion 611. Thus, the undoped semiconductor layer 615, the first semiconductor layer 620, the active layer 625, and the second semiconductor layer 630 are sequentially grown on the growth substrate 605.

The undoped semiconductor layer 615 can include an undoped nitride semiconductor. For example, a nitride semiconductor can be made of a GaN-based semiconductor material. An upper surface of the undoped semiconductor layer 615 can be positioned at a level lower than a level of an upper surface of the second pattern portion 611 of the passivation pattern 613.

The first semiconductor layer 620 can be formed on top of the undoped semiconductor layer 615 and can include a nitride semiconductor containing the first conductivity-type impurities. For example, the first conductivity-type impurities can include N-type impurities. The nitride semiconductor can be made of a GaN-based semiconductor material including GaN, AlGaN, InGaN, or AlInGaN. The N-type impurities used for doping of the first semiconductor layer 620 can include silicon (Si), germanium (Ge), selenium (Se), tellurium (Te), or carbon (C).

An upper surface of the first semiconductor layer 620 can be positioned at a level higher than that of the upper surface of the second pattern portion 611 of the passivation pattern 613. Accordingly, the upper surface and an upper portion of the side surface of the second pattern portion 611 of the passivation pattern 613 can be surrounded with the first semiconductor layer 620.

The active layer 625 can be disposed on the upper surface of the first semiconductor layer 620 and can act as a layer for emitting light based on the combination of holes and electrons. The active layer 625 can have the multi-quantum well (MQW) structure having a well layer and a barrier layer having a higher band gap than that of the well layer.

The second semiconductor layer 630 is formed on the active layer 625. The second semiconductor layer 630 can provide holes to the active layer 625 and can be made of the nitride semiconductor containing the P-type impurities as the second conductivity-type impurities. The nitride semiconductor can be made of a GaN-based semiconductor material including GaN, AlGaN, InGaN, or AlInGaN. The P-type impurities contained in the second semiconductor layer 630 can include manganese (Mg), zinc (Zn), or beryllium (Be).

In one example, in the present disclosure, an example in which the first semiconductor layer 620 and the second semiconductor layer 630 are made of the nitride semiconductor containing the N-type impurities and the nitride semiconductor including the P-type impurities, respectively is described. However, the present disclosure is not limited thereto. In another example, the first semiconductor layer 620 and the second semiconductor layer 630 can be made of a nitride semiconductor containing the P-type impurities and a nitride semiconductor containing the N-type impurities, respectively.

During the epitaxy process, an area of the nitride semiconductor layer is reduced by a size of an area where the second pattern portion 611 of the passivation pattern 613 is disposed. Accordingly, the nitride semiconductor structure can be grown while minimizing the contact area between the growth substrate 605 and the nitride semiconductor layer, such that the quality of the nitride semiconductor layer can be improved.

Referring to FIG. 18C, a patterning process for separating and spacing adjacent nitride semiconductor structures 635 from each other is performed. The patterning process can be performed based on an etching process using a mask pattern having an opening OA1 defined therein exposing a portion of an upper surface of the first pattern portion 610 of the passivation pattern 613 between adjacent nitride semiconductor structures 635. The etching process is performed such that the exposed portion of the first pattern portion 610 of the passivation pattern 613 exposed through the opening OA1 of the mask pattern is etched away until the surface of the growth substrate 605 is exposed. Thus, the nitride semiconductor structures 635 can be separated and spaced from each other. In one example, the etching process can be performed in a dry etching scheme using an inductively coupled plasma-reactive ion etch (ICP-RIE) using reactive gas.

An outer side surface of the nitride semiconductor structure 635 is entirely surrounded with the first pattern portion 610 of the passivation pattern 613. Further, the upper surface of the nitride semiconductor structure 635 is covered with the mask pattern during the etching process. Accordingly, the plasma-induced damage occurs only on the side surface of the first pattern portion 610 of the passivation pattern 613 during the dry etching process. Accordingly, the occurrence of an abnormal combinations of electrons and holes that do not participate in light emission due to the plasma-induced damage to the nitride semiconductor structure can be suppressed, such that the light-emitting efficiency can be prevented from being reduced.

Further, the epitaxy process is performed while the second pattern portion 611 of the passivation pattern 613 is disposed on the growth substrate 605. Thus, during the epitaxy process, the nitride semiconductor layer can be grown while minimizing the contact area between the growth substrate 605 and the nitride semiconductor layer, such that the quality of the nitride semiconductor layer can be improved.

Further, the second pattern portion 611 of the passivation pattern 613 can be partially inserted into the lower portion of the nitride semiconductor structure. Thus, the lower portion of the nitride semiconductor structure can have a relatively smaller area than that of the upper portion thereof. Accordingly, the current injection efficiency can be improved due to the current confinement phenomenon.

Referring to FIG. 18D, a process of removing the growth substrate 605 from the nitride semiconductor structures in the laser lift-off manner is performed to obtain light-emitting elements 600a, 600b, and 600c which are spaced and separated from each other. The first electrode 640 is formed on (e.g., under or below) a surface of the undoped semiconductor layer 615 of the light-emitting element 600 and thus is electrically connected to the first semiconductor layer 620, while the second electrode 645 is formed on the upper surface of the second semiconductor layer 630 and is electrically connected thereto. In one example, the first electrode 640 can be formed to have a size such that the first electrode 640 covers an area where the second pattern portion 611 of the passivation pattern 613 is disposed. However, the present disclosure is not limited thereto.

The first electrode 640 and/or the second electrode 645 can be embodied as a single layer or multiple layers made of a conductive material such as titanium (Ti), chromium (Cr), aluminum (Al), or gold (Au). This light-emitting element 600 can have the vertical-type structure and can be the same as the light-emitting element 600 of FIG. 10A.

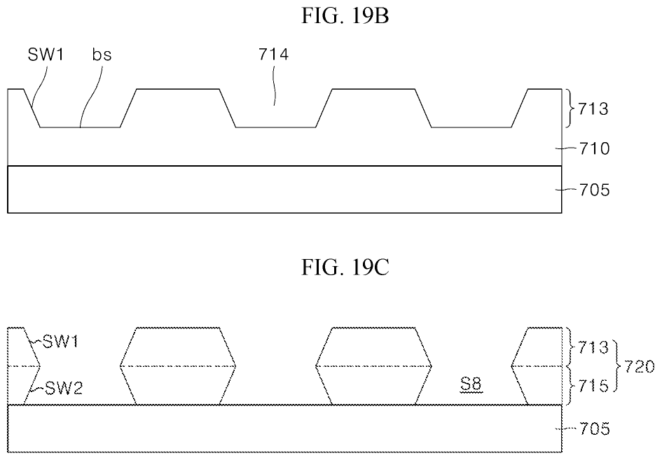

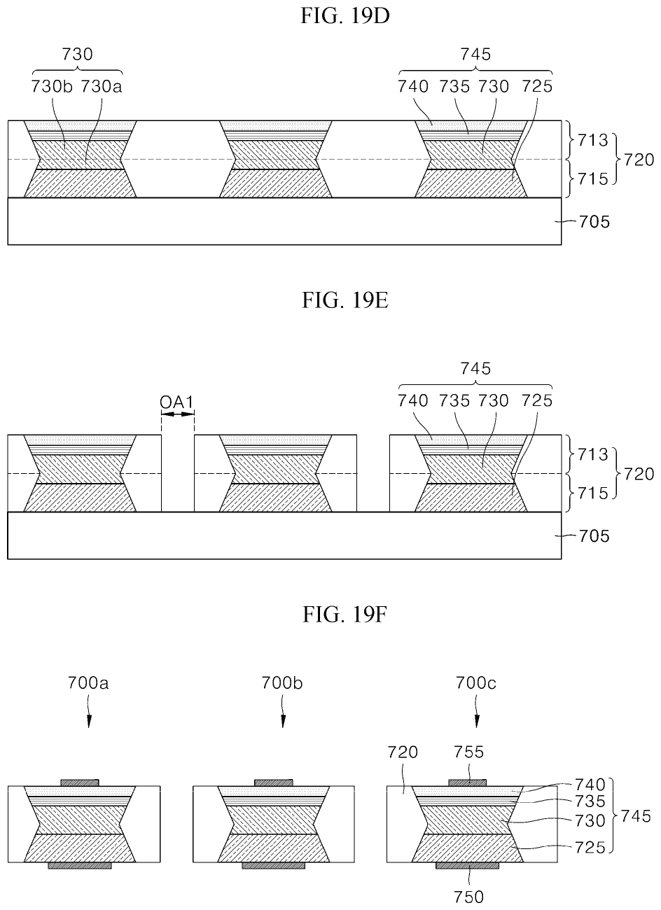

FIG. 19A to FIG. 19F are cross-sectional views illustrating a method for manufacturing the light-emitting element (e.g., 700 in FIG. 11A) according to the eighth embodiment of the present disclosure.

Referring to FIG. 19A, a passivation layer 710 is formed on a growth substrate 705. The growth substrate 10 can include a material such as sapphire, silicon (Si), silicon carbide (SiC) or gallium arsenide (GaAs). However, the present disclosure is not limited thereto. The passivation layer 710 can be made of a material on which the nitride-based semiconductor cannot grow, for example, an insulating material. Subsequently, a mask pattern 712 is formed on the passivation layer 710. The mask pattern 712 can have an opening defined therein that exposes a portion of the upper surface of the passivation layer 710. The mask pattern 712 can be formed by applying a photosensitive material such as a photoresist material on the passivation layer 710 and performing a photo process including exposure and development processes thereon.

Referring to FIG. 19B, a first etching process of etching the upper surface of the passivation layer 710 using a mask pattern 712 as an etching mask is performed to form a head portion 713 of the passivation pattern. The head portion 713 of the passivation pattern can be defined by a trench 714 formed in the passivation layer 710. The trench 714 can include a first sidewall surface SW1 and a bottom surface BS which defines the head portion 713 of the passivation pattern.

The first etching process can be performed in a dry etching scheme, and can be performed in an etching scheme using plasma. Such dry etching can have anisotropic etching characteristics. In this regard, adjusting a process condition of the dry etching scheme can allow the head portion 713 of the passivation pattern to be formed such that a width thereof gradually larger as the head portion 713 extends toward the bottom surface BS of the trench 714. Accordingly, the first sidewall surface SW1 of the trench 714 can have a first slope in a first direction with respect to the bottom surface BS, and the head portion 713 of the passivation pattern can have a tapered shape.

The first sidewall surface SW1 of the trench 714 is illustrated as having a straight line shape in an example of the present disclosure. However, the present disclosure is not limited thereto. For example, the first sidewall surface SW1 can be curved.

Referring to FIG. 19C, a second etching process is performed on the passivation layer 710 in which the trench 714 has been formed to form the column portion 715 of the passivation pattern. The passivation pattern 720 including the column portion 715 and the head portion 713 can be formed on the growth substrate 705 by performing the second etching process for patterning the passivation layer 710.

The second etching process can be performed in a wet etching scheme. Such a wet etching scheme can have isotropic etching characteristics in which etching is uniformly performed in vertical and horizontal directions. Then, as the etching is performed on the bottom surface BS of the trench 714, a second sidewall surface SW2 having a second slope in a second direction can be formed. In this regard, the second slope in the second direction has a positive slope while the first slope in the first direction has a negative slope.

Further, the column portion 715 of the passivation pattern 720 can have a reverse tapered shape in which a width thereof is gradually smaller as the column portion 715 extends toward the growth substrate 705. The second sidewall surface SW2 having the second slope is shown as having a straight line shape in an example of the present disclosure. However, the present disclosure is not limited thereto. For example, the second sidewall surface SW2 can be curved. The second etching process can be performed until the surface of the growth substrate 705 is exposed.

Accordingly, an inner space S8 in which the nitride semiconductor structure is to be formed can be positioned between adjacent passivation patterns 720. The inner space S8 formed between the passivation patterns 720 can include an upper space positioned between both side ends of the head portions 713 of the passivation patterns 720 and a lower space positioned between the column portions 715 of the passivation patterns 720.

In this regard, the inner space S8 defined between the adjacent passivation patterns 720 can have a polygonal shape in a cross-sectional view. For example, the inner space S8 can have an hourglass shape.

Referring to FIG. 19D, an epitaxy process is performed on the growth substrate 705 and the passivation pattern 720 to form the nitride semiconductor structure 745.

When the epitaxy process is performed, the undoped semiconductor layer 725, the first semiconductor layer 730, the active layer 735, and the second semiconductor layer 740 are sequentially formed on the growth substrate 705 and in the inner space S8 between adjacent passivation patterns 720. The undoped semiconductor layer 725 can include an undoped nitride semiconductor. For example, the nitride semiconductor can be made of a GaN-based semiconductor material.

The first semiconductor layer 730 can include a nitride semiconductor containing the first conductivity-type impurities. For example, the first conductivity-type impurities can include the N-type impurities. The nitride semiconductor can be made of a GaN-based semiconductor material including GaN, AlGaN, InGaN, or AlInGaN. The N-type impurities as the first conductivity-type impurities can include silicon (Si), germanium (Ge), selenium (Se), tellurium (Te), or carbon (C).

The first semiconductor layer 730 can be disposed on an upper surface of the undoped semiconductor layer 725, and can have the lower portion 730a whose a width decreases as the lower portion extends upwardly to a top level of the column portion 715 and the upper portion 730b whose a width increases as the upper portion extends upwardly.

The active layer 735 can be positioned on top of the upper portion 730b of the first semiconductor layer 730 and can act as a layer for emitting light based on the combination of holes and electrons. The active layer 735 can have a multi-quantum well (MQW) structure having a well layer and a barrier layer having a higher band gap than that of the well layer. The active layer 735 has a shape in which a width thereof increases as the active layer extends upwardly.

The second semiconductor layer 740 is formed on the active layer 735 and has a shape whose a width thereof increases as the second semiconductor layer 740 extends upwardly. The second semiconductor layer 740 can be made of a nitride semiconductor containing the P-type impurities as the second conductivity-type impurities. The nitride semiconductor can be made of a GaN-based semiconductor material including GaN, AlGaN, InGaN, or AlInGaN. The P-type impurities contained in the second semiconductor layer 740 can include manganese (Mg), zinc (Zn), or beryllium (Be).

In one example, in the present disclosure, an example in which the first semiconductor layer 730 and the second semiconductor layer 740 are made of the nitride semiconductor containing the N-type impurities and the nitride semiconductor including the P-type impurities, respectively is described. However, the present disclosure is not limited thereto. In another example, the first semiconductor layer 730 and the second semiconductor layer 740 can be made of a nitride semiconductor containing the P-type impurities and a nitride semiconductor containing the N-type impurities, respectively.

The upper surface of the second semiconductor layer 740 disposed as a top level of the nitride semiconductor structure 745 can be coplanar with the upper surface of the passivation pattern 720. The passivation pattern 720 can have a shape surrounding the entirety of the outer side surface of the nitride semiconductor structure 745 except for an upper surface thereof.

The nitride semiconductor structure 745 can have a shape in which a width thereof decreases as the nitride semiconductor structure 745 extends upwardly from the lower surface of the undoped semiconductor layer 725 and then increases as the nitride semiconductor structure 745 extends upwardly from the upper portion of the first semiconductor layer 730 to the second semiconductor layer 740. Accordingly, in a cross-sectional view, the nitride semiconductor structure 745 can have an hourglass shape in which the width thereof is the smallest at a median vertical level, and is the largest at each of a top level and a bottom level.

Referring to FIG. 19E, a patterning process is performed on the nitride semiconductor structure 745 sand the passivation pattern 720 to separate and space adjacent nitride semiconductor structures 745 from each other. To this end, a mask layer is formed on an exposed surface of the passivation pattern 720 and an exposed surface of the second semiconductor layer 740, and a photo process including exposure and development processes is performed thereon to form a mask pattern having an opening OA1 defined therein exposing a portion of the upper surface of the passivation pattern 720.

Subsequently, an etching process is performed on the portion of the passivation pattern 720 exposed through the opening OA1 of the mask pattern until the surface of the growth substrate 705 is exposed, thereby separating and spacing the adjacent nitride semiconductor structures 745 from each other. In this regard, the etching process can be performed in a dry etching scheme using an inductively coupled plasma-reactive ion etch (ICP-RIE) using reactive gas.

The outer side surface of the nitride semiconductor structure 745 is entirely surrounded with the passivation pattern 720. Further, as the upper surface of the second semiconductor layer 740 is covered with the mask pattern during the dry etching process. Thus, the damage that can be caused by plasma occurs only to the passivation pattern 720, while the damage due to the plasma does not occur to the nitride semiconductor structure 745. This can fundamentally prevent the occurrence of the abnormal combinations of electrons and holes that do not participate in light emission due to the plasma-induced damage to the nitride semiconductor structure, thereby preventing the decrease in light-emitting efficiency.

Referring to FIG. 19F, a process of removing the growth substrate 705 from the nitride semiconductor structures 745 in the laser lift-off manner is performed to obtain the individual light-emitting elements 700a, 700b, and 700c as spaced and separated from each other.

Then, the first electrode 750 is formed on (e.g., under or below) a surface of the undoped semiconductor layer 725 of each of the nitride semiconductor structures 745 and thus is electrically connected to the first semiconductor layer 730 thereof, while the second electrode 755 is formed on an upper surface of the second semiconductor layer 740 and is electrically connected thereto.

The first electrode 750 and/or the second electrode 755 can be embodied as a single layer or multiple layers made of a conductive material such as titanium (Ti), chromium (Cr), aluminum (Al), or gold (Au).

The light-emitting element 700 of FIG. 11A and FIG. 19F according to the seventh embodiment of the present disclosure can have the upper and lower sidewall surfaces respectively having the first slope and the second slope different from each other and thus have a polygonal shape in a cross-sectional view. Accordingly, as shown in FIG. 11B, as the light continues to encounter different interfaces thereof, an angle of incidence thereto continues to change. Thus, a light amount emitted to the outside can increase such that the light extraction efficiency can be improved.

Further, as the outer side surface of the nitride semiconductor structure 745 is covered with the passivation pattern 720 during the dry etching process, the damage caused by plasma thereto can be suppressed. This can prevent the abnormal combinations of electrons and holes that do not participate in light emission due to the plasma-induced damage, thereby improving the light-emitting efficiency.

According to various embodiments of the present invention, one or more features from one embodiment can be applied to another embodiment, or a modified version of one or more features from one embodiment can be used or applied to another embodiment.

Although the embodiments of the present disclosure have been described in more detail with reference to the accompanying drawings, the present disclosure is not necessarily limited to these embodiments, and can be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. A light-emitting device comprising:
a nitride semiconductor structure including a first semiconductor layer, an active layer and a second semiconductor layer;
a passivation pattern disposed on opposing side surfaces of the nitride semiconductor structure;
a first electrode electrically connected to the first semiconductor layer; and
a second electrode electrically connected to the second semiconductor layer,
wherein an upper surface of the passivation pattern is substantially coplanar with an upper surface of the second semiconductor layer.

2. The light-emitting device of claim 1, wherein the nitride semiconductor structure further includes an undoped semiconductor layer disposed under the first semiconductor layer.

3. The light-emitting device of claim 1, wherein one side surface of the nitride semiconductor structure is aligned in a line, and
wherein another side surface opposite to the one side surface of the nitride semiconductor structure has a step so that a portion of an upper surface of the first semiconductor layer is exposed.

4. The light-emitting device of claim 3, wherein the passivation pattern has a contact hole exposing a portion of the exposed portion of the upper surface of the first semiconductor layer,
wherein the first electrode includes:
a column portion filling the contact hole to be connected to the first semiconductor layer; and
a head portion extending from the column portion and disposed on an upper surface of the passivation pattern, and
wherein at least a partial area of the second electrode overlaps the upper surface of the passivation pattern.

5. The light-emitting device of claim 1, wherein each of the second semiconductor layer and the active layer has a first width,
wherein the first semiconductor layer includes an upper portion having a width equal to the first width, and a lower portion having a second width larger than the first width, and
wherein the lower portion of the first semiconductor layer has a protruding portion extending outwardly beyond each of opposing sidewalls of the upper portion of the first semiconductor layer, wherein the protruding portion has an exposed upper surface.

6. The light-emitting device of claim 5, wherein the passivation pattern has a contact hole exposing a portion of the exposed upper surface of the protruding portion of the lower portion of the first semiconductor layer at one side of the lower portion,
wherein the first electrode includes:
a column portion filling the contact hole to be connected to the first semiconductor layer; and
a head portion extending from the column portion and disposed on the upper surface of the passivation pattern,
wherein at least a partial area of the second electrode overlaps the upper surface of the passivation pattern.

7. The light-emitting device of claim 1, wherein side surfaces of the first semiconductor layer, the active layer, and the second semiconductor layer in the nitride semiconductor structure are aligned to each other.

8. The light-emitting device of claim 1, wherein the nitride semiconductor structure further includes an undoped semiconductor layer disposed under the first semiconductor layer,
wherein the undoped semiconductor layer has a protruding portion extending outwardly beyond an outer side surface of at least one of the first semiconductor layer, the active layer, and the second semiconductor layer, and the protruding portion of the undoped semiconductor layer has an exposed upper surface, and
wherein the passivation pattern is disposed on the exposed upper surface of the protruding portion of the undoped semiconductor layer.

9. The light-emitting device of claim 1, wherein each of the second semiconductor layer and the active layer has a first width,
wherein the first semiconductor layer includes an upper portion having a width equal to the first width, and a lower portion having a second width smaller than the first width so that the first semiconductor layer has a step at each of opposing side surfaces thereof, and
wherein the nitride semiconductor structure further includes an undoped semiconductor layer having a width equal to the second width.

10. The light-emitting device of claim 9, wherein the passivation pattern covers opposing sidewalls of each of the second semiconductor layer and the active layer, covers opposing sidewalls and a bottom surface of the upper portion of the first semiconductor layer, and covers opposing sidewalls of each of the lower portion of the first semiconductor layer and the undoped semiconductor layer.

11. The light-emitting device of claim 1, wherein the nitride semiconductor structure has a T-shape in a cross-sectional view of the light-emitting device, or an inverse T-shape in a cross-section view of the light-emitting device.

12. The light-emitting device of claim 1, wherein the nitride semiconductor structure further includes an undoped semiconductor layer disposed under the first semiconductor layer, and
wherein the passivation pattern includes:
a first pattern portion surrounding an outer side surface of the nitride semiconductor structure; and
a second pattern portion including a plurality of column portions spaced apart from each other, wherein each of the plurality of column portions extends through the undoped semiconductor layer to be disposed in the first semiconductor layer.

13. The light-emitting device of claim 1, wherein the nitride semiconductor structure further includes an undoped semiconductor layer disposed under the first semiconductor layer, and
wherein the nitride semiconductor structure has:
a first slanted side wall surface having a first slope in a first direction so that a width of the nitride semiconductor structure decreases from the second semiconductor layer toward the first semiconductor layer in the first direction; and
a second slanted side wall surface extending from the first slanted side wall surface and having a second slope in a second direction being different from the first direction, so that the width of the nitride semiconductor structure increases from the first semiconductor layer toward the undoped semiconductor layer in the second direction.

14. The light-emitting device of claim 1, wherein in a cross-sectional view of the light-emitting device, the nitride semiconductor structure has a substantially hourglass shape having a smallest width at a median vertical level of the nitride semiconductor structure.

15. The light-emitting device of claim 1, wherein the passivation pattern includes:
a head portion having a taper shape; and
a column portion extending from the head portion and having a reverse taper shape.

16. The light-emitting device of claim 1, wherein the passivation pattern includes a non-conductive material.

17. The light-emitting device of claim 1, wherein each of at least one of the first electrode and the second electrode has at least one of an exposed upper surface and an exposed side surface.

18. The light-emitting device of claim 2, wherein the second electrode, the undoped semiconductor layer, the second electrode, and the second semiconductor layer are disposed in a concentric configuration.

19. A method for manufacturing a light-emitting device, the method comprising:
forming a plurality of body portions of a passivation pattern on a growth substrate so as to be spaced apart from each other via first spaces;
forming an undoped semiconductor layer and a lower portion of a first semiconductor layer in the first spaces;
forming an extension of the passivation pattern on each of the body portions of the passivation pattern so as to overlap a portion of the lower portion of the first semiconductor layer;
forming an upper portion of the first semiconductor layer, an active layer, and a second semiconductor layer in second spaces defined between adjacent extensions of the passivation pattern, thereby forming nitride semiconductor structures;
etching the passivation pattern to separate the nitride semiconductor structures from each other; and
removing the growth substrate from the nitride semiconductor structures.

20. The method of claim 19, further comprising:
after separating the adjacent nitride semiconductor structures from each other and for each of the nitride semiconductor structures:
forming a contact hole extending through the passivation pattern so as to expose a portion of a surface of the lower portion of the first semiconductor layer;
forming a first electrode so that the first electrode includes a column portion filling the contact hole so as to be connected to the exposed portion of the surface of the lower portion of the first semiconductor layer, and a head portion extending from the column portion so as to be disposed on an upper surface of the passivation pattern; and
forming a second electrode on a surface of the second semiconductor layer so that a portion of a lower surface of the second electrode overlaps the upper surface of the passivation pattern.

21. The method of claim 19, wherein the etching the passivation pattern includes etching the passivation pattern in a dry etching scheme using plasma.

22. The method of claim 19, wherein the nitride semiconductor structures are separated from each other so that for each nitride semiconductor structure, a remaining portion of the passivation pattern after the etching thereof surrounds an outer side surface of the nitride semiconductor structure.

23. The method of claim 19, wherein the passivation pattern includes an insulating material on which a nitride semiconductor does not grow.

24. A method for manufacturing a light-emitting device, the method comprising:
forming a plurality of passivation patterns on a growth substrate so as to be spaced apart from each other via spaces, each space having a shape corresponding to a shape of a nitride semiconductor structure;
forming a nitride semiconductor structure in each space defined between adjacent passivation patterns, wherein the nitride semiconductor structure includes a first semiconductor layer, an active layer, and a second semiconductor layer;
exposing a portion of an upper surface of each of the passivation patterns;
etching the exposed portion of the upper surface of the passivation pattern until a surface of the growth substrate is exposed, thereby separating adjacent nitride semiconductor structures from each other; and
removing the growth substrate from the nitride semiconductor structures.

25. The method of claim 24, wherein the forming the nitride semiconductor structure further includes forming an undoped semiconductor layer under the first semiconductor layer.

26. The method of claim 25, wherein the undoped semiconductor layer has a width equal to a width of each of the first semiconductor layer, the active layer, and the second semiconductor layer.

27. The method of claim 25, wherein the undoped semiconductor layer has a portion protruding outwardly beyond an outer sidewall of each of the first semiconductor layer, the active layer, and the second semiconductor layer so that the undoped semiconductor layer has a width larger than a width of each of the first semiconductor layer, the active layer, and the second semiconductor layer, and
wherein the passivation pattern is disposed on an upper surface of the protruding portion of the undoped semiconductor layer.

28. The method of claim 24, wherein the passivation pattern has:
a column portion having a reverse taper shape in which a width thereof gradually decreases as the column portion extends toward the growth substrate; and
a head portion extending from the column portion and having a taper shape in which a width thereof gradually decreases as the head portion extends toward the second semiconductor layer.

29. The method of claim 24, wherein each nitride semiconductor structure has a substantially hourglass shape in which a width thereof is the smallest at a median vertical level thereof and is the largest at each of bottom and top levels thereof.

30. The method of claim 25, wherein for each nitride semiconductor structure, the passivation pattern includes:
a first pattern portion having a same height as a height of the nitride semiconductor structure; and
a second pattern portion including a plurality of column portions spaced apart from each other and positioned inwardly of the first pattern portion,
wherein each of the plurality of column portions has a height smaller than the height of the first pattern portion, and extends through the undoped semiconductor layer into the first semiconductor layer.

31. A method for manufacturing a light-emitting device, the method comprising:
forming a plurality of body portions of a passivation pattern on a growth substrate so as to be spaced apart from each other via a first space;
forming an undoped semiconductor layer and a lower portion of a first semiconductor layer in the first space;
forming a head portion on each body portion of the passivation pattern so as to have a smaller width than a width of the body portion, so that a second space having a width larger than a width of the first space is defined between adjacent head portions;
sequentially forming an upper portion of the first semiconductor layer, an active layer, and a second semiconductor layer on the lower portion of the first semiconductor layer and in the second space, thereby forming adjacent nitride semiconductor structures;
exposing a portion of an upper surface of the head portion of the passivation pattern;
etching the exposed portion of the upper surface of the head portion of the passivation pattern until a surface of the growth substrate is exposed, thereby separating the adjacent nitride semiconductor structures from each other; and
removing the growth substrate from the nitride semiconductor structures.

32. The method of claim 31, wherein the passivation pattern includes an insulating material on which a nitride semiconductor does not grow.

33. The method of claim 31, wherein the separating the adjacent nitride semiconductor structures from each other is performed so that a remaining portion of the passivation pattern after the etching thereof surrounds an outer side surface of the corresponding nitride semiconductor structure.

34. The method of claim 31, wherein the passivation pattern is etched in a dry etching scheme using plasma.
